(19) United States
(12) Patent Application Publication
(10) Pub. No.: US 2025/0155813 A1
(43) Pub. Date: May 15, 2025

(54) PROTECTIVE FILM FORMING COMPOSITION

(71) Applicant: NISSAN CHEMICAL CORPORATION, Tokyo (JP)

(72) Inventor: Satoshi KAMIBAYASHI, Toyama-shi (JP)

(73) Assignee: NISSAN CHEMICAL CORPORATION, Tokyo (JP)

(21) Appl. No.: 18/833,574

(22) PCT Filed: Jan. 26, 2023
(86) PCT No.: PCT/JP2023/002406

§ 371 Date: Jul. 26, 2024

(30) Foreign Application Priority Data
Feb. 2, 2022 (JP) 2022-015051

(51) Int. Cl. G03F 7/11; C08G 59/26; C08G 59/42; C08K 5/13; G03F 7/16; H01L 21/311

(52) U.S. Cl. CPC G03F 7/11; C08G 59/26; C08G 59/4207; C08G 59/4215; C08G 59/4223; C08G 59/423; C08K 5/13; G03F 7/168; H01L 21/31138; H01L 21/31144

(57) ABSTRACT

A protective film forming composition for forming a protective film that protects an inorganic film formed on a surface of a semiconductor substrate against wet etching, the protective film forming composition including:
a polymer having a partial structure represented by Formula (A) and a solvent.

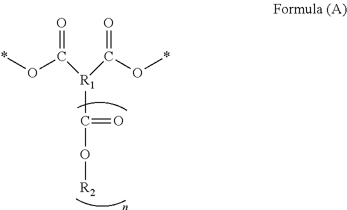

In Formula (A), R₁ is an (n+2)-valent organic group, R₂ is a hydrogen atom or an alkyl group having 1 to 13 carbon atoms which may be substituted with a substituent, n is 1 or 2, and * is a bond.

### TECHNICAL FIELD

The present invention relates to a composition for forming a protective film excellent in resistance particularly to a semiconductor wet etching solution in a lithography process in semiconductor manufacturing. The present invention also relates to a protective film formed of the composition, a method for manufacturing a substrate with a resist pattern to which the protective film is applied, and a method for manufacturing a semiconductor device.

### BACKGROUND ART

In semiconductor manufacturing, a lithography process that includes providing a resist underlayer film between a substrate and a resist film formed on the substrate and forming a resist pattern having a desired shape is widely known. The substrate is processed after the resist pattern is formed, and dry etching is mainly used as the process, but wet etching may be used for substrates of certain kinds. Patent Literature 1 discloses a resist underlayer film material having resistance to an alkaline hydrogen peroxide solution.

### CITATION LIST

### Patent Literature

Patent Literature 1: JP 2018-173520 A

### SUMMARY OF INVENTION

### Technical Problem

When a protective film for a semiconductor substrate is formed using a protective film forming composition, and a base substrate is processed by wet etching using the protective film as an etching mask, the protective film is required to have a good masking performance (that is, the masked portion can protect the substrate) against a semiconductor wet etching solution and resistance to a solvent contained in a resist composition (solvent resistance). In addition, it is required to fill a microstructure, which has been miniaturized, on a semiconductor substrate with a resin without voids.

The present invention has been made in view of the above circumstances, and an object of the present invention is to provide a protective film forming composition capable of filling a microstructure with a resin without voids, and capable of forming a protective film excellent in resistance to a semiconductor wet etching solution and excellent in resistance to a solvent contained in a resist composition. Another object of the present invention is to provide a protective film formed of the protective film forming composition, a method for manufacturing a substrate with a resist pattern to which the protective film is applied, and a method for manufacturing a semiconductor device.

### Solution to Problem

As a result of intensive studies to solve the above-described problems, the present inventors have found that the above-described problems can be solved by introducing a partial structure represented by Formula (A) into a polymer contained in a protective film forming composition, and have completed the present invention.

That is, the present invention includes the following aspects.
[1] A protective film forming composition for forming a protective film that protects an inorganic film formed on a surface of a semiconductor substrate against wet etching, the protective film forming composition including:
a polymer having a partial structure represented by Formula (A) and a solvent,

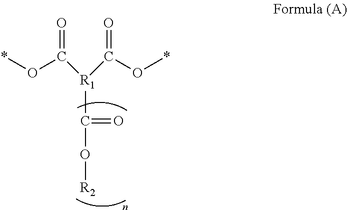

in Formula (A), R₁ is an (n+2)-valent organic group, R₂ is a hydrogen atom or an alkyl group having 1 to 13 carbon atoms which may be substituted with at least one group selected from the group consisting of an alkoxy group having 1 to 13 carbon atoms, an alkylcarbonyloxy group having 2 to 13 carbon atoms, an alkoxycarbonyl group having 2 to 13 carbon atoms, an alkylthio group having 1 to 13 carbon atoms, a nitro group, an alkylsulfonyloxy group having 1 to 13 carbon atoms, and an alkoxysulfonyl group having 1 to 13 carbon atoms, n is 1 or 2, when n is 2, two R₂ may be same or different, and * is a bond.
[2] The protective film forming composition according to [1], wherein the polymer has a repeating unit represented by Formula (1):

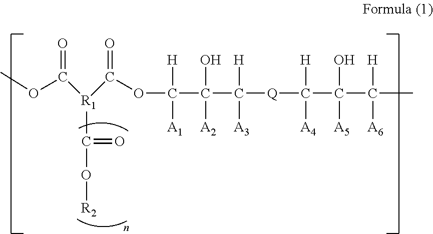

in Formula (1), A₁, A₂, A₃, A₄, A₅, and A₆ are each independently a hydrogen atom, a methyl group, or an ethyl group, Q is a divalent organic group, R₁ is an (n+2)-valent organic group, R₂ is a hydrogen atom or an alkyl group having 1 to 13 carbon atoms which may be substituted with at least one group selected from the group consisting of an alkoxy group having 1 to 13 carbon atoms, an alkylcarbonyloxy group having 2 to 13 carbon atoms, an alkoxycarbonyl group having 2 to 13 carbon atoms, an alkylthio group having 1 to 13 carbon atoms, a nitro group, an alkylsulfonyloxy group having 1 to 13 carbon atoms, and an alkoxysulfonyl group having 1 to 13 carbon atoms, n is 1 or 2, and when n is 2, two R₂ may be same or different.
[3] The protective film forming composition according to [1] or [2], wherein the polymer further has a partial structure represented by Formula (B) different from the partial structure represented by Formula (A),

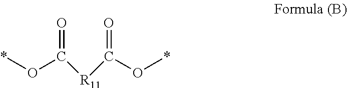

in Formula (B), Ru is a divalent organic group, and * is a bond.
[4] The protective film forming composition according to [2] or [3], wherein Q in Formula (1) is a divalent organic group represented by Formula (3):

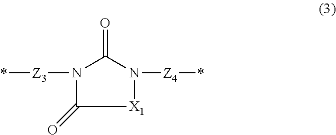

in Formula (3), X₁ is a divalent group represented by Formula (4), Formula (5), or Formula (6), Z₃ and Z₄ are each independently a direct bond or a divalent group represented by Formula (7), and * is a bond,

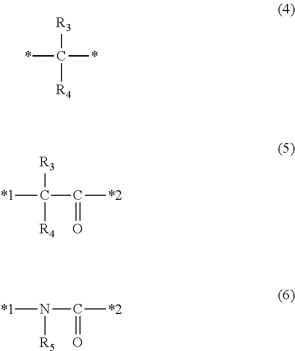

wherein in Formulas (4) and (5), R₃ and R₄ are each independently a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group, or a phenyl group, the phenyl group may be substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R₃ and R₄ may be bonded to each other to form a ring having 3 to 6 carbon atoms, * is a bond, *1 is a bond bonded to a carbon atom, and *2 is a bond bonded to a nitrogen atom,
wherein in Formula (6), Rs is a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group, or a phenyl group, the phenyl group may be substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, *1 is a bond bonded to a carbon atom, and *2 is a bond bonded to a nitrogen atom,

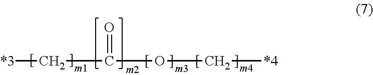

in Formula (7), m1 is an integer of 0 to 4, m2 is 0 or 1, m3 is 0 or 1, m4 is an integer of 0 to 2, provided that when m3 is 1, m1 and m2 do not simultaneously become 0, *3 is a bond bonded to a nitrogen atom, and *4 is a bond bonded to a carbon atom.
[5] The protective film forming composition according to any one of [1] to [4], further including a crosslinking agent.
[6] The protective film forming composition according to any one of [1] to [5], further including a compound that is at least one of a compound represented by Formula (1a) and a compound represented by Formula (1b):

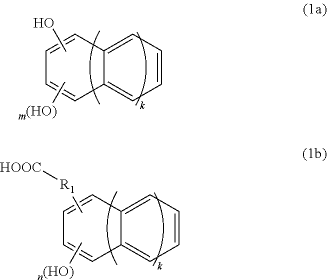

in Formulas (1a) and (1b), R₁ is a single bond, an alkylene group having 1 to 4 carbon atoms, or an alkenylene group having 2 to 4 carbon atoms which has one or two carbon-carbon double bonds, k is 0 or 1, m is an integer of 1 to 3, and n is an integer of 2 to 4.
[7] A protective film against a semiconductor wet etching solution, the protective film being a baked product of a coating film formed of the protective film forming composition according to any one of [1] to [6].
[8] A method for manufacturing a substrate with a protective film, the method including a step of applying the protective film forming composition according to any one of [1] to [6] onto a semiconductor substrate having steps and baking the protective film forming composition to form the protective film.
[9] A method for manufacturing a substrate with a resist pattern that is used in semiconductor manufacturing, the method including:
a step of applying the protective film forming composition according to any one of [1] to [6] onto a semiconductor substrate and baking the protective film forming composition to form a protective film as a resist underlayer film; and
a step of forming a resist film directly on the protective film or with another layer interposed between the resist film and the protective film, and then performing exposure and development to form the resist pattern.
[10] A method for manufacturing a semiconductor device, the method including: a step of forming a protective film using the protective film forming composition according to any one of [1] to [6] on a semiconductor substrate having an inorganic film formed on a surface; a step of forming a resist pattern directly on the protective film or with another layer interposed between the resist pattern and the protective film; a step of dry etching the protective film using the resist pattern as a mask to expose a surface of the inorganic film; and a step of wet etching and cleaning the inorganic film with a semiconductor wet etching solution using the protective film after dry etching as a mask.

### Advantageous Effects of Invention

According to the present invention, it is possible to provide a protective film forming composition capable of filling a microstructure with a resin without voids, and capable of forming a protective film excellent in resistance to a semiconductor wet etching solution and excellent in resistance to a solvent contained in a resist composition. Further, according to the present invention, it is possible to provide a protective film formed of the protective film forming composition, a method for manufacturing a substrate with a resist pattern to which the protective film is applied, and a method for manufacturing a semiconductor device.

### BRIEF DESCRIPTION OF DRAWINGS

FIG. 1 is a schematic view of a cross-sectional shape of trenches.

FIG. 2 is a cross-sectional photograph (SEM photograph) of trenches in which a protective film of Example 5 is formed.

FIG. 3 is a cross-sectional photograph (SEM photograph) of a case of filling failure.

### DESCRIPTION OF EMBODIMENTS

### (Protective Film Forming Composition)

The protective film forming composition of the present invention is a composition for forming a protective film.

The protective film is a protective film that protects an inorganic film formed on a surface of a semiconductor substrate against wet etching.

The protective film forming composition contains a polymer and a solvent.

### <Polymer>

The polymer contained in the protective film forming composition has a partial structure represented by Formula (A).

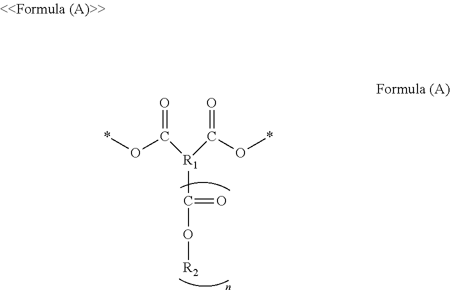

In Formula (A), R₁ is an (n+2)-valent organic group, R₂ is a hydrogen atom or an alkyl group having 1 to 13 carbon atoms which may be substituted with at least one group selected from the group consisting of an alkoxy group having 1 to 13 carbon atoms, an alkylcarbonyloxy group having 2 to 13 carbon atoms, an alkoxycarbonyl group having 2 to 13 carbon atoms, an alkylthio group having 1 to 13 carbon atoms, a nitro group, an alkylsulfonyloxy group having 1 to 13 carbon atoms, and an alkoxysulfonyl group having 1 to 13 carbon atoms, n is 1 or 2, when n is 2, two R₂ may be the same or different, and * is a bond.

The bond in Formula (A) is preferably bonded to a carbon atom.

### <<Formula (1)>>

The polymer preferably has a repeating unit represented by Formula (1). For example, the partial structure represented by Formula (A) is a part of the repeating unit represented by Formula (1).

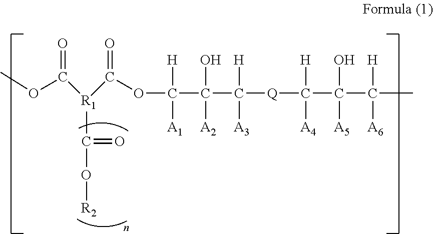

In Formula (1), A₁, A₂, A₃, A₄, A₅, and A₆ are each independently a hydrogen atom, a methyl group, or an ethyl group, Q is a divalent organic group, R₁ is an (n+2)-valent organic group, R₂ is a hydrogen atom or an alkyl group having 1 to 13 carbon atoms which may be substituted with at least one group selected from the group consisting of an alkoxy group having 1 to 13 carbon atoms, an alkylcarbonyloxy group having 2 to 13 carbon atoms, an alkoxycarbonyl group having 2 to 13 carbon atoms, an alkylthio group having 1 to 13 carbon atoms, a nitro group, an alkylsulfonyloxy group having 1 to 13 carbon atoms, and an alkoxysulfonyl group having 1 to 13 carbon atoms, n is 1 or 2, and when n is 2, two R₂ may be the same or different.

### <<<R₁>>>

In Formula (A) and Formula (1), R₁ is an (n+2)-valent organic group.

The number of carbon atoms of the (n+2)-valent organic group is not particularly limited, but is preferably 2 to 30, more preferably 4 to 20, and particularly preferably 4 to 15.

The (n+2)-valent organic group preferably has an aromatic hydrocarbon ring or an aliphatic hydrocarbon ring. Examples of the aromatic hydrocarbon ring include a benzene ring, a naphthalene ring, and an anthracene ring. Examples of the aliphatic hydrocarbon ring include a cyclobutane ring, a cyclopentane ring, and a cyclohexane ring.

Examples of R₁ include the following trivalent organic groups. The following trivalent organic group may be substituted with an alkyl group, an alkylcarbonyl group, a hydroxy group, an alkoxy group, an alkoxycarbonyl group, a halogen atom, a nitro group, a combination of two or more thereof, or the like. In each formula below, * is a bond.

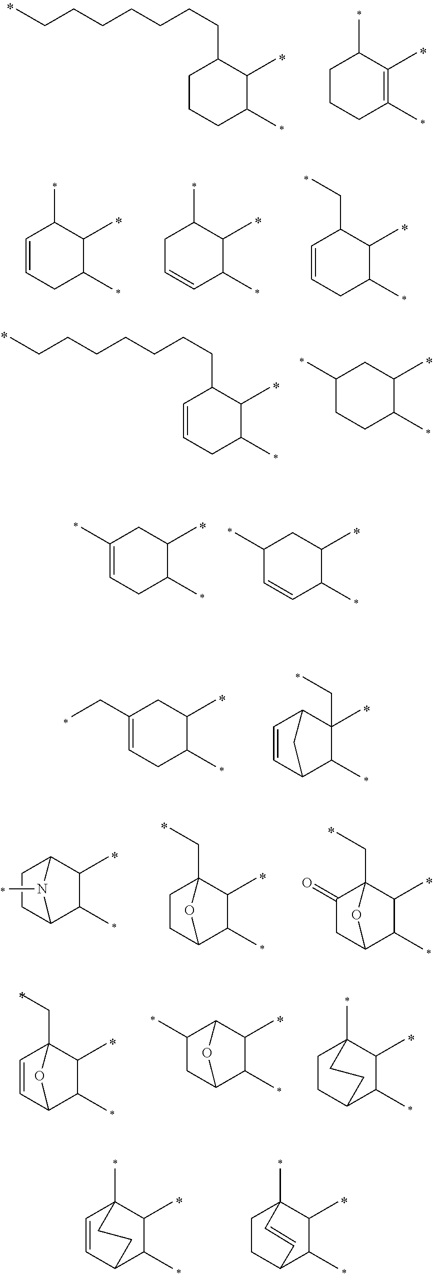

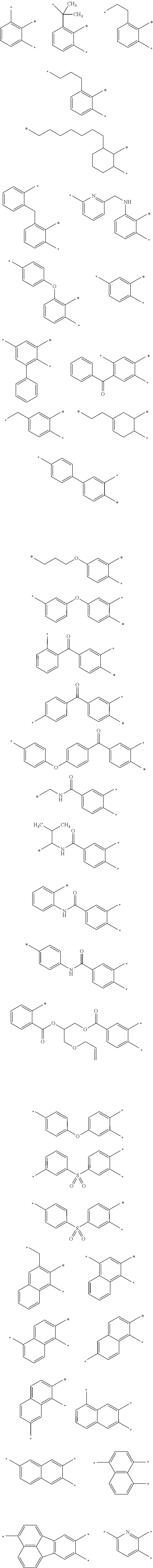

The trivalent organic group is preferably a trivalent organic group represented by the following formula.

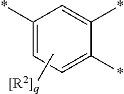

In the formula, q is an integer of 0 to 3, R₂ is an alkyl group having 1 to 6 carbon atoms or an alkoxy group having 6 carbon atoms or less, provided that when q is 2 or 3, R₂ may be the same or different, and * is a bond.

Examples of R₁ include the following tetravalent organic groups.

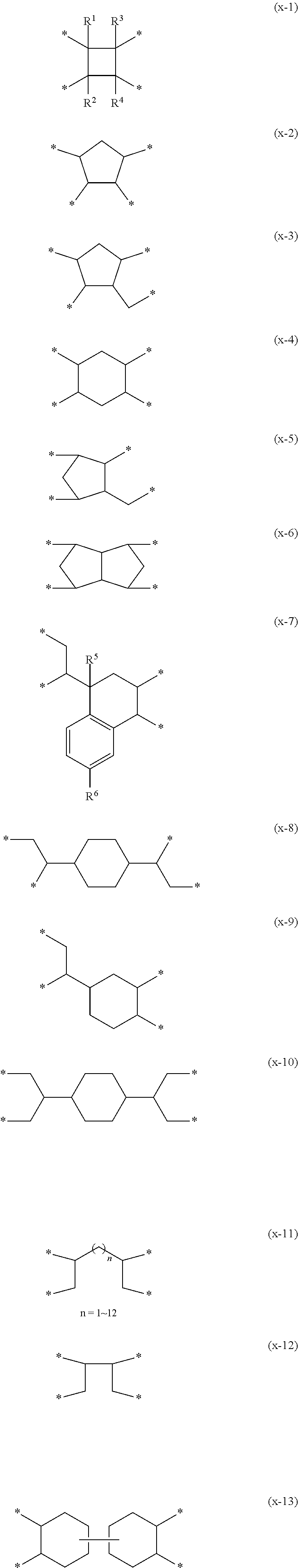

In Formulas (x-1) to (x-13), R¹ to R⁴ are each independently a hydrogen atom, a halogen atom, an alkyl group having 1 to 6 carbon atoms, an alkenyl group having 2 to 6 carbon atoms, an alkynyl group having 2 to 6 carbon atoms, a monovalent organic group having 1 to 6 carbon atoms which has a fluorine atom, or a phenyl group, R⁵ and R⁶ are each independently a hydrogen atom or a methyl group, and * is a bond.

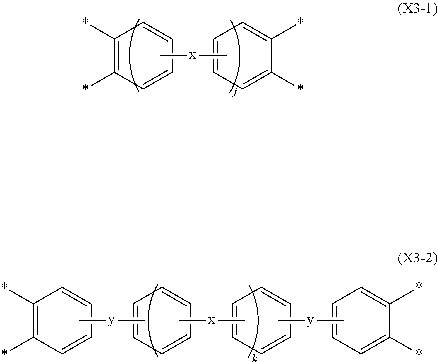

In Formulas (X3-1) and (X3-2), x and y are each independently a single bond, an ether bond, a carbonyl group, an ester bond, an alkanediyl group having 1 to 5 carbon atoms, 1,4-phenylene, a sulfonyl bond, or an amide group, j and k are integers of 0 or 1, and * is a bond.

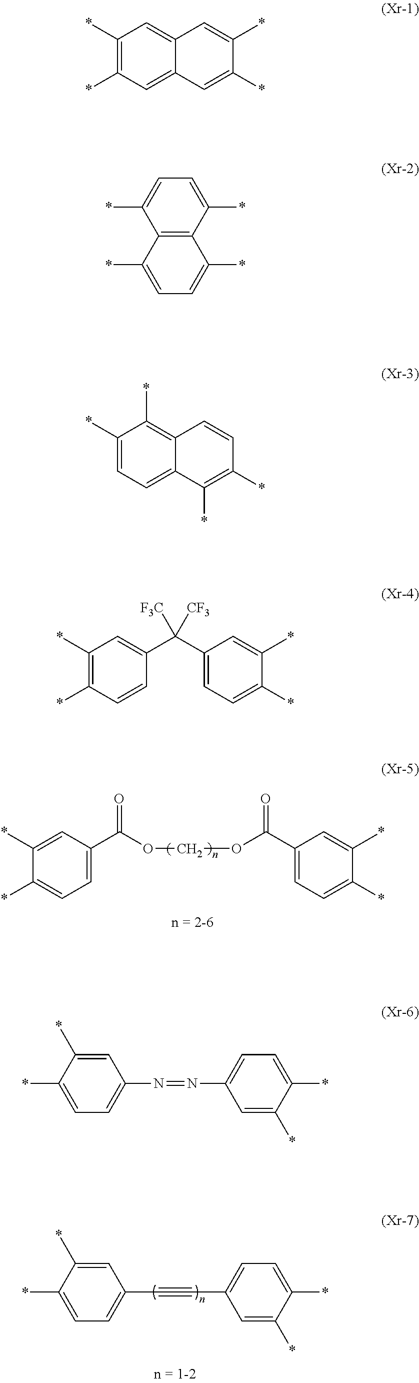

Herein, * is a bond.

The tetravalent organic group represented by Formula (X3-1) or (X3-2) may have a structure represented by any one of Formulas (X3-3) to (X3-19).

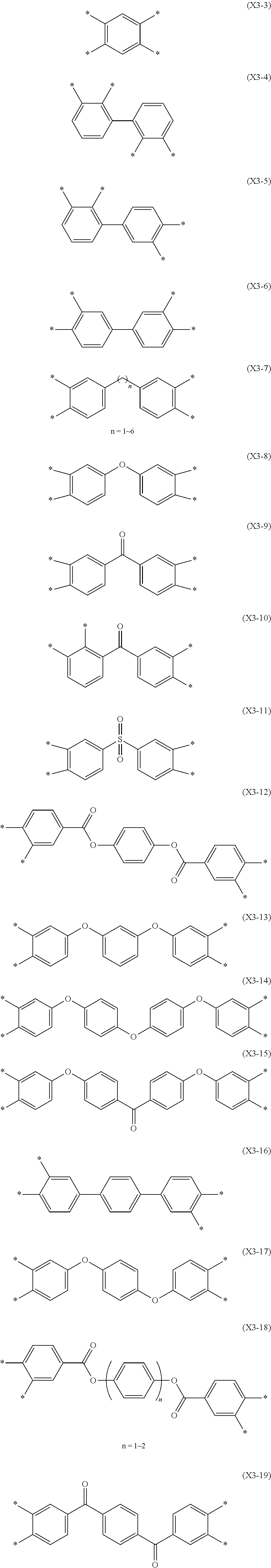

Herein, * is a bond.

### <<<R₂>>>

In Formula (A) and Formula (1), R₂ is a hydrogen atom or an optionally substituted alkyl group having 1 to 13 carbon atoms.

The alkyl group having 1 to 13 carbon atoms may be substituted with at least one group selected from the group consisting of an alkoxy group having 1 to 13 carbon atoms, an alkylcarbonyloxy group having 2 to 13 carbon atoms, an alkoxycarbonyl group having 2 to 13 carbon atoms, an alkylthio group having 1 to 13 carbon atoms, a nitro group, an alkylsulfonyloxy group having 1 to 13 carbon atoms, and an alkoxysulfonyl group having 1 to 13 carbon atoms.

The alkyl group having 1 to 13 carbon atoms is preferably an alkyl group having 1 to 8 carbon atoms, and more preferably an alkyl group having 1 to 6 carbon atoms.

The alkoxy group having 1 to 13 carbon atoms is preferably an alkoxy group having 1 to 8 carbon atoms, and more preferably an alkoxy group having 1 to 6 carbon atoms.

The alkylcarbonyloxy group having 2 to 13 carbon atoms is preferably an alkylcarbonyloxy group having 2 to 8 carbon atoms, and more preferably an alkylcarbonyloxy group having 2 to 6 carbon atoms.

The alkoxycarbonyl group having 2 to 13 carbon atoms is preferably an alkoxycarbonyl group having 2 to 8 carbon atoms, and more preferably an alkoxycarbonyl group having 2 to 6 carbon atoms.

The alkylthio group having 1 to 13 carbon atoms is preferably an alkylthio group having 1 to 8 carbon atoms, and more preferably an alkylthio group having 1 to 6 carbon atoms.

The alkylsulfonyloxy group having 1 to 13 carbon atoms is preferably an alkylsulfonyloxy group having 1 to 8 carbon atoms, and more preferably an alkylsulfonyloxy group having 1 to 6 carbon atoms.

The alkoxysulfonyl group having 1 to 13 carbon atoms is preferably an alkoxysulfonyl group having 1 to 8 carbon atoms, and more preferably an alkoxysulfonyl group having 1 to 6 carbon atoms.

In the present description, the alkyl group is not limited to a linear form, and may be a branched form or a cyclic form. Examples of the linear or branched alkyl group include a methyl group, an ethyl group, an isopropyl group, a tert-butyl group, and a n-hexyl group. Examples of the cyclic alkyl group (cycloalkyl group) include a cyclobutyl group, a cyclopentyl group, and a cyclohexyl group.

In the present description, examples of the alkoxy group include a methoxy group, an ethoxy group, a n-pentyloxy group, and an isopropoxy group.

In the present description, examples of the alkylcarbonyloxy group include a methylcarbonyloxy group and an ethylcarbonyloxy group.

In the present description, examples of the alkoxycarbonyl group include a methoxycarbonyl group, an ethoxycarbonyl group, and an isopropoxycarbonyl group.

In the present description, examples of the alkylthio group include a methylthio group, an ethylthio group, a n-pentylthio group, and an isopropylthio group.

In the present description, examples of the alkenyl group include an ethenyl group, a 1-propenyl group, a 2-propenyl group, a 1-methyl-1-ethenyl group, a 1-butenyl group, a 2-butenyl group, a 3-butenyl group, a 2-methyl-1-propenyl group, and a 2-methyl-2-propenyl group.

In the present description, examples of the alkynyl group include groups in which a double bond of the alkenyl groups listed above as “alkenyl group” is replaced with a triple bond.

In the present description, examples of the halogen atom include a fluorine atom, a chlorine atom, a bromine atom, and an iodine atom.

R₂ is preferably an alkyl group having 1 to 13 carbon atoms or an alkyl group having 1 to 13 carbon atoms substituted with an alkoxy group having 1 to 13 carbon atoms from the viewpoint that the effect of the present invention is suitably obtained.

When n is 2, two R₂ are preferably the same.

### <<<Q>>>

In Formula (1), Q is a divalent organic group. The divalent organic group is not particularly limited, but is preferably a divalent organic group having a hetero atom, and more preferably a divalent organic group having a nitrogen atom and an oxygen atom. Examples of the hetero atom include a nitrogen atom, an oxygen atom, and a sulfur atom.

The number of carbon atoms in the divalent organic group is not particularly limited, but is preferably 3 to 30, and more preferably 3 to 20.

Examples of Q include a divalent organic group represented by Formula (2) and a divalent organic group represented by Formula (3). Among them, a divalent organic group represented by Formula (3) is preferable from the viewpoint that the effect of the present invention is suitably obtained.

*—Z₁-Q₁-Z₂—* (2)
In Formula (2),
Q₁ is
   a direct bond,
   a divalent organic group represented by Formula (3),
   an alkylene group having 1 to 10 carbon atoms which may be interrupted by —O—, —S—, or —S—S—,
   an alkenylene group having 2 to 6 carbon atoms which may be interrupted by —O—, —S—, or —S—S—, or
   a divalent organic group having at least one alicyclic hydrocarbon ring having 3 to 10 carbon atoms or an aromatic hydrocarbon ring having 6 to 14 carbon atoms which may be interrupted by —O—, —S—, or —S—S—,
   the divalent organic group may be substituted with at least one group selected from the group consisting of an alkyl group having 1 to 6 carbon atoms, an alkenyl group having 2 to 6 carbon atoms, an alkynyl group having 2 to 6 carbon atoms, a halogen atom, a hydroxy group, a nitro group, a cyano group, a methylidene group, an alkoxy group having 1 to 6 carbon atoms, an alkoxycarbonyl group having 1 to 6 carbon atoms, and an alkylthio group having 1 to 6 carbon atoms,
   Z₁ and Z₂ are each —COO—, —OCO—, —O—, or —S—, and * is a bond.

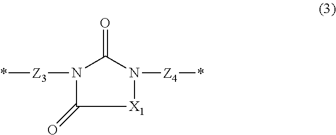

In Formula (3), X₁ is a divalent group represented by Formula (4), Formula (5), or Formula (6), Z₃ and Z₄ are each independently a direct bond or a divalent group represented by Formula (7), and * is a bond.

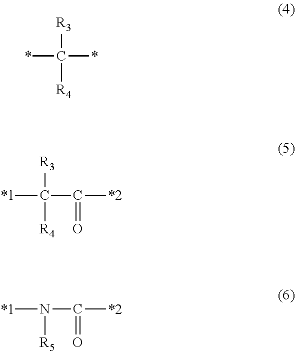

In Formulas (4) and (5), R₃ and R₄ are each independently a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group, or a phenyl group, the phenyl group may be substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R₃ and R₄ may be bonded to each other to form a ring having 3 to 6 carbon atoms, * is a bond, *1 is a bond bonded to a carbon atom, and *2 is a bond bonded to a nitrogen atom.

In Formula (6), Rs is a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group, or a phenyl group, the phenyl group may be substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, *1 is a bond bonded to a carbon atom, and *2 is a bond bonded to a nitrogen atom.

Examples of the alkyl group having 1 to 10 carbon atoms which may be interrupted by an oxygen atom or a sulfur atom include an alkyl group having 1 to 10 carbon atoms, an alkoxy group having 1 to 10 carbon atoms, an alkoxyalkyl group having 1 to 10 carbon atoms, an alkoxyalkoxyalkyl group having 1 to 10 carbon atoms, an alkylthio group having 1 to 10 carbon atoms, and an alkylthioalkyl group having 1 to 10 carbon atoms.

The alkyl group having 1 to 10 carbon atoms which may be interrupted by an oxygen atom or a sulfur atom may contain two or more oxygen atoms or sulfur atoms.

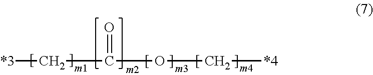

In Formula (7), m1 is an integer of 0 to 4, m2 is 0 or 1, m3 is 0 or 1, m4 is an integer of 0 to 2, provided that when m3 is 1, m1 and m2 do not simultaneously become 0, *3 is a bond bonded to a nitrogen atom, and *4 is a bond bonded to a carbon atom.

X₁ in Formula (3) is preferably a divalent group represented by Formula (6) from the viewpoint that the effect of the present invention is suitably obtained.

### <<Formula (B)>>

The polymer preferably further has a partial structure represented by Formula (B) different from the partial structure represented by Formula (A) from the viewpoint of better groove filling ability of a protective film formed of the protective film forming composition and the viewpoint of being easily dissolved in a solvent in the protective film forming composition.

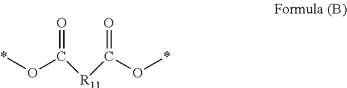

In Formula (B), R₁₁ is a divalent organic group, and * is a bond.

R₁₁ in Formula (B) is a group different from R₁(C(═O)OR₂) n in Formula (A).

The bond in Formula (B) is preferably bonded to a carbon atom.

### <<Formula (11)>>

The polymer preferably further has a repeating unit represented by Formula (11) different from the repeating unit represented by Formula (1) from the viewpoint of better groove filling ability of a protective film formed of the protective film forming composition and the viewpoint of being easily dissolved in a solvent in the protective film forming composition. For example, the partial structure represented by Formula (B) is a part of a repeating unit represented by Formula (11).

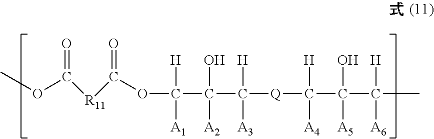

In Formula (11), A₁, A₂, A₃, A₄, A₅, and A₆ are each independently a hydrogen atom, a methyl group, or an ethyl group, Q is a divalent organic group, and Ru is a divalent organic group.

R₁₁ in Formula (11) is a group different from R₁(C(═O)OR₂)n in Formula (1).

Examples of Q include Q in Formula (1).

Examples of R₁₁ include a divalent organic group having 2 to 30 carbon atoms. Examples of the divalent organic group having 2 to 30 carbon atoms include an alkylene group having 2 to 10 carbon atoms.

R₁₁ is, for example, a residue obtained by removing two carboxy groups from a dicarboxylic acid.

Examples of the dicarboxylic acid include aliphatic dicarboxylic acids, alicyclic dicarboxylic acids, and aromatic group-containing dicarboxylic acids.

Examples of the aliphatic dicarboxylic acid include malonic acid, dimethylmalonic acid, succinic acid, fumaric acid, glutaric acid, adipic acid, muconic acid, 2-methyladipic acid, trimethyladipic acid, pimelic acid, 2,2-dimethylglutaric acid, 3,3-diethylsuccinic acid, azelaic acid, sebacic acid, and suberic acid.

Examples of the alicyclic dicarboxylic acid include 1,1-cyclopropanedicarboxylic acid, 1,2-cyclopropanedicarboxylic acid, 1,1-cyclobutanedicarboxylic acid, 1,2-cyclobutanedicarboxylic acid, 1,3-cyclobutanedicarboxylic acid, 3,4-diphenyl-1,2-cyclobutanedicarboxylic acid, 2,4-diphenyl-1,3-cyclobutanedicarboxylic acid, 3,4-bis(2-hydroxyphenyl)-1,2-cyclobutanedicarboxylic acid, 2,4-bis(2-hydroxyphenyl)-1,3-cyclobutanedicarboxylic acid, 1-cyclobutene-1,2-dicarboxylic acid, 1-cyclobutene-3,4-dicarboxylic acid, 1,1-cyclopentanedicarboxylic acid, 1,2-cyclopentanedicarboxylic acid, 1,3-cyclopentanedicarboxylic acid, 1,1-cyclohexanedicarboxylic acid, 1,2-cyclohexanedicarboxylic acid, 1,3-cyclohexanedicarboxylic acid, 1,4-cyclohexanedicarboxylic acid, 1,4-(2-norbornene) dicarboxylic acid, norbornene-2,3-dicarboxylic acid, bicyclo[2.2.2]octane-1,4-dicarboxylic acid, bicyclo[2.2.2]octane-2,3-dicarboxylic acid, 2,5-dioxo-1,4-bicyclo[2.2.2]octanedicarboxylic acid, 1,3-adamantanedicarboxylic acid, 4,8-dioxo-1,3-adamantanedicarboxylic acid, 2,6-spiro[3.3]heptanedicarboxylic acid, and 1,3-adamantanediacetic acid.

Examples of the aromatic group-containing dicarboxylic acid include o-phthalic acid, isophthalic acid, terephthalic acid, 5-methylisophthalic acid, 5-tert-butylisophthalic acid, 5-aminoisophthalic acid, 5-hydroxyisophthalic acid, 2,5-dimethylterephthalic acid, tetramethylterephthalic acid, 1,4-naphthalenedicarboxylic acid, 2,5-naphthalenedicarboxylic acid, 2,6-naphthalenedicarboxylic acid, 2,7-naphthalenedicarboxylic acid, 1,4-anthracenedicarboxylic acid, 1,4′-anthraquinone dicarboxylic acid, 2,5-biphenyldicarboxylic acid, 4,4′-biphenyldicarboxylic acid, 1,5-biphenylenedicarboxylic acid, 4,4″-terphenyldicarboxylic acid, 4,4′-diphenylmethanedicarboxylic acid, 4,4′-diphenylethanedicarboxylic acid, 4,4′-diphenylpropanedicarboxylic acid, 4,4′-diphenylhexafluoropropanedicarboxylic acid, 4,4′-diphenyl ether dicarboxylic acid, 4,4′-bibenzyldicarboxylic acid, 4,4′-stilbenedicarboxylic acid, 4,4′-tolandicarboxylic acid, 4,4′-carbonyldibenzoic acid, 4,4′-sulfonyldibenzoic acid, 4,4′-dithiodibenzoic acid, p-phenylenediacetic acid, 3,3′-p-phenylenedipropionic acid, 4-carboxycinnamic acid, p-phenylenediacrylic acid, 3,3′-(4-4′-(methylenedi-p-phenylene))dipropionic acid, 4,4′-(4,4′-(oxydi-p-phenylene))dipropionic acid, 4,4′-(4,4′-(oxydi-p-phenylene))dibutyric acid, (isopropylidenedi-p-phenylenedioxy) dibutyric acid, bis(p-carboxyphenyl)dimethylsilane, 1,5-(9-oxofluorene) dicarboxylic acid, 3,4-furandicarboxylic acid, 4,5-thiazoledicarboxylic acid, 2-phenyl-4,5-thiazoledicarboxylic acid, 1,2,5-thiadiazole-3,4-dicarboxylic acid, 1,2,5-oxadiazole-3,4-dicarboxylic acid, 2,3-pyridinedicarboxylic acid, 2,4-pyridinedicarboxylic acid, 2,5-pyridinedicarboxylic acid, 2,6-pyridinedicarboxylic acid, 3,4-pyridinedicarboxylic acid, 3,5-pyridinedicarboxylic acid, and 6-pyridinedicarboxylic acid.

When the polymer has the partial structure (B′) represented by Formula (B), the molar ratio between the partial structure (A′) represented by Formula (A) and the partial structure (B′) represented by Formula (B) in the polymer ((A′):(B′)) is not particularly limited, but is preferably from 1:99 to 95:5, more preferably from 5:95 to 80:20, and particularly preferably from 10:90 to 60:40.

When the polymer has the repeating unit (1′) represented by Formula (1) and the repeating unit (11′) represented by Formula (11), the molar ratio between the repeating unit (1′) represented by Formula (1) and the repeating unit (11′) represented by Formula (11) in the polymer ((1′):(11′)) is not particularly limited, but is preferably from 1:99 to 95:5, more preferably from 5:95 to 80:20, and particularly preferably from 10:90 to 60:40.

When the polymer has the repeating unit (1′) represented by Formula (1), the molar ratio of the repeating unit (1′) represented by Formula (1) in all the repeating units of the polymer is not particularly limited, but is preferably 1 mol % or more and 95 mol % or less, more preferably 5 mol % or more and 80 mol % or less, and particularly preferably 10 mol % or more and 40 mol % or less.

When the polymer has the repeating unit (11′) represented by Formula (11), the molar ratio of the repeating unit (11′) represented by Formula (11) in all the repeating units of the polymer is not particularly limited, but is preferably 5 mol % or more and 99 mol % or less, more preferably 20 mol % or more and 95 mol % or less, and particularly preferably 40 mol % or more and 90 mol % or less.

### <<Method for Manufacturing Polymer>>

The method for manufacturing the polymer is not particularly limited, and examples thereof include a method in which at least one of a tetracarboxylic acid dianhydride represented by Formula (A₁) and a tricarboxylic acid anhydride represented by Formula (A₂), a diepoxy compound represented by Formula (2A), and a compound represented by Formula (C) are reacted. In this case, a polymer having a repeating unit represented by Formula (1) is obtained.

For example, at least one of a tetracarboxylic acid dianhydride represented by Formula (A₁) and a tricarboxylic acid anhydride represented by Formula (A₂), and a diepoxy compound represented by Formula (2A) at an appropriate molar ratio are dissolved in an organic solvent containing a large excess amount of a compound represented by Formula (C). A polymer is obtained by polymerization in the presence of a catalyst that activates an epoxy group.

When R₂ is a hydrogen atom, the compound represented by Formula (C) is not used, and another inert organic solvent is used.

Examples of the method for manufacturing a polymer include a method in which at least one of a tetracarboxylic acid dianhydride represented by Formula (A1) and a tricarboxylic acid anhydride represented by Formula (A2), a diepoxy compound represented by Formula (2A), a dicarboxylic acid represented by Formula (B1), and a compound represented by Formula (C) are reacted. In this case, a polymer having a repeating unit represented by Formula (1) and a repeating unit represented by Formula (11) is obtained.

For example, at least one of a tetracarboxylic acid dianhydride represented by Formula (A1) and a tricarboxylic acid anhydride represented by Formula (A2), a diepoxy compound represented by Formula (2A), and a dicarboxylic acid represented by Formula (B1) at an appropriate molar ratio are dissolved in an organic solvent containing a large excess amount of a compound represented by Formula (C). A polymer is obtained by polymerization in the presence of a catalyst that activates an epoxy group.

When R² is a hydrogen atom, the compound represented by Formula (C) is not used, and another inert organic solvent is used.

Examples of the catalyst for activating an epoxy group include a quaternary phosphonium salt such as tetrabutylphosphonium bromide or ethyltriphenylphosphonium bromide, and a quaternary ammonium salt such as benzyltriethylammonium chloride. As the amount of the catalyst used, an appropriate amount can be selected and used from the range of 0.1 to 10 mass % with respect to the total mass of the polymer raw material used in the reaction. As the temperature and time for the polymerization reaction, for example, optimum conditions can be selected from the range of 80 to 160° C. and 2 to 50 hours.

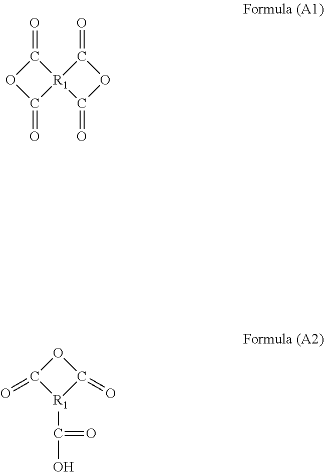

In Formula (A1) and Formula (A2), R¹ is as defined for R₁ in Formula (1).

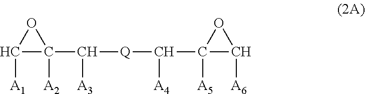

In Formula (2A), A₁, A₂, A₃, A₄, A₅, A₆, and Q are as defined for A₁, A₂, A₃, A₄, A₅, A₆, and Q in Formula (1), respectively.

HO—R₂ Formula (C)

In Formula (C), R₂ is as defined for R₂ in Formula (1).

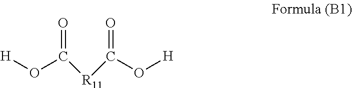

In Formula (B1), R₁₁ is as defined for R₁₁ in Formula (11).

Examples of the diepoxy compound represented by Formula (2A) include the following diepoxy compounds.

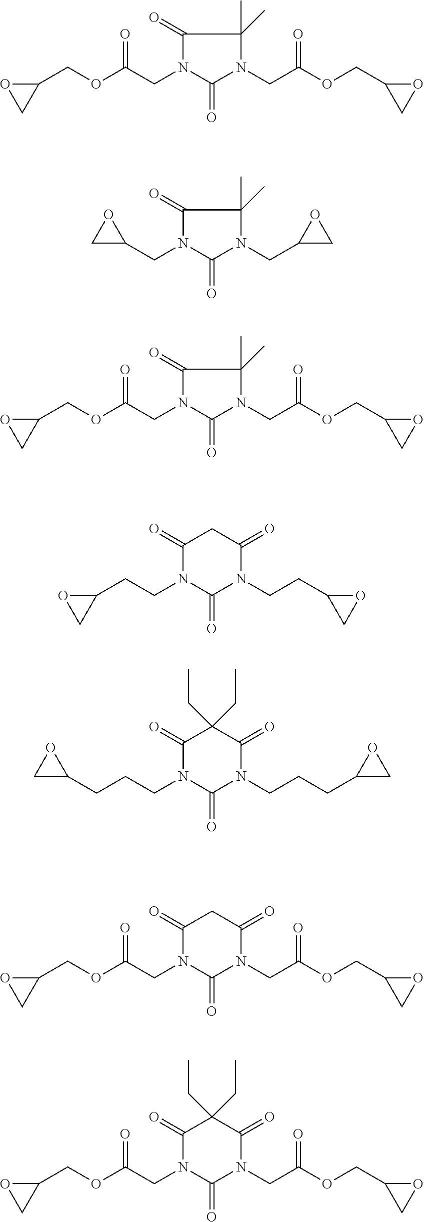

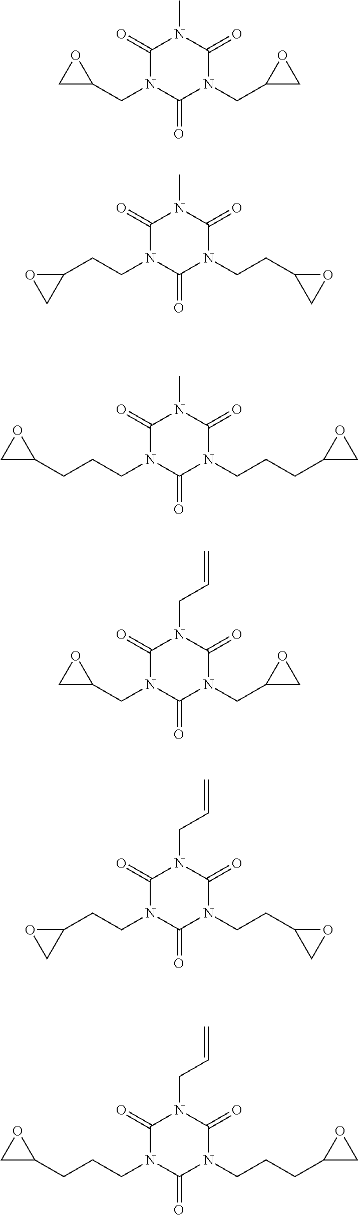

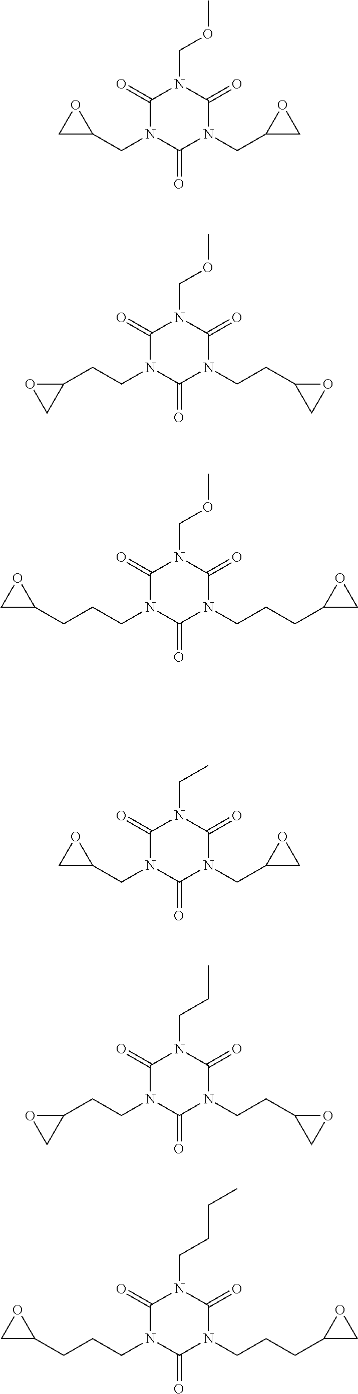 [SMILES: COCn1c(=O)n(CC2CO2)c(=O)n(CC2CO2)c1=O ; COCn1c(=O)n(CCC2CO2)c(=O)n(CCC2CO2)c1=O ; COCn1c(=O)n(CCCC2CO2)c(=O)n(CCCC2CO2)c1=O ; CCn1c(=O)n(CC2CO2)c(=O)n(CC2CO2)c1=O ; CCCn1c(=O)n(CCC2CO2)c(=O)n(CCC2CO2)c1=O ; CCCCn1c(=O)n(CCCC2CO2)c(=O)n(CCCC2CO2)c1=O]

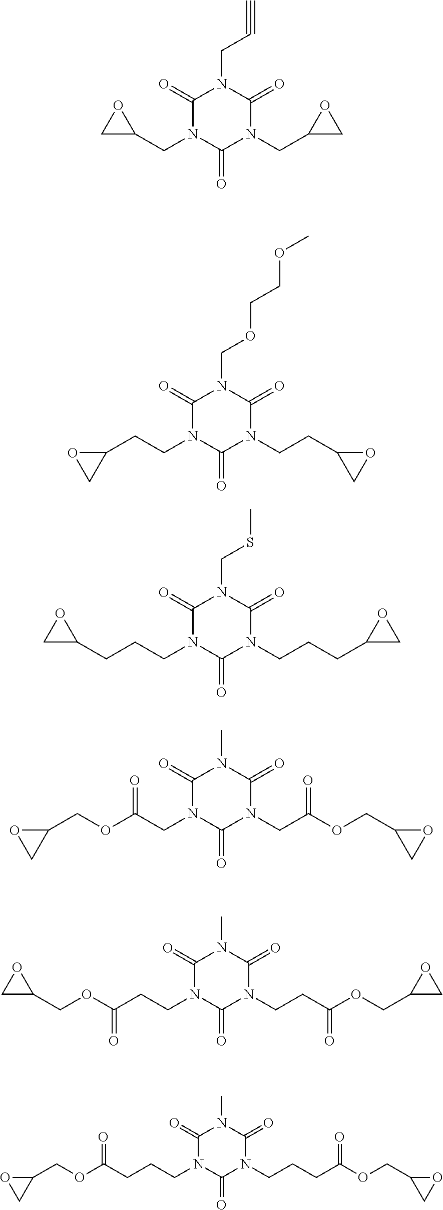

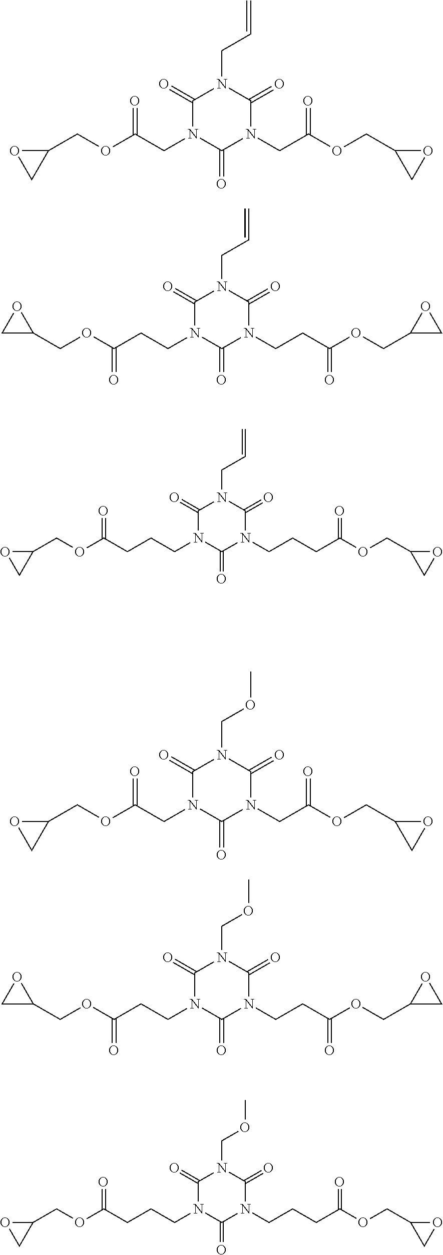

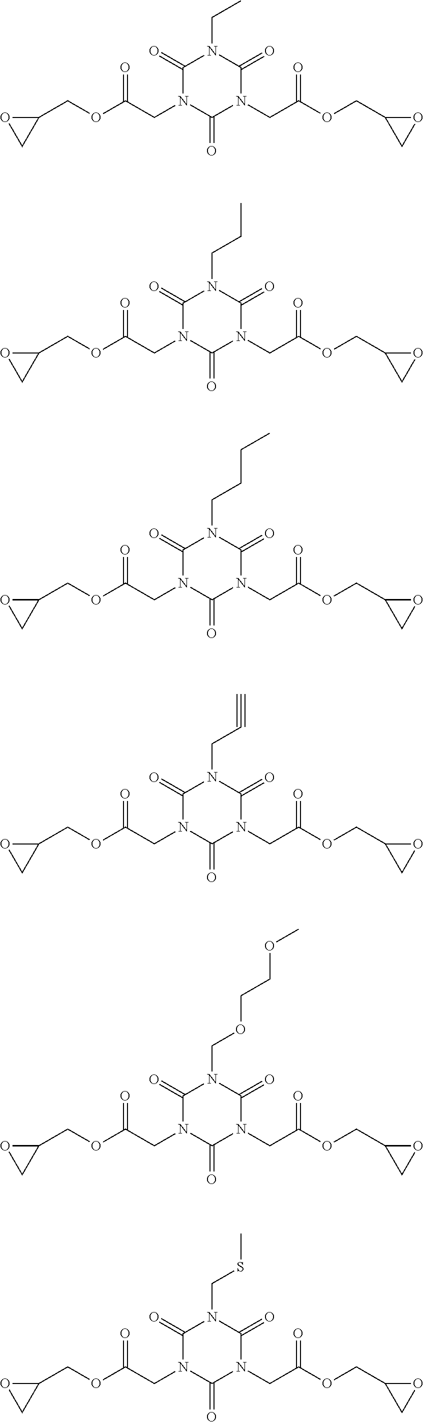 [SMILES: CCn1c(=O)n(CC(=O)OCC2CO2)c(=O)n(CC(=O)OCC2CO2)c1=O ; CCCn1c(=O)n(CC(=O)OCC2CO2)c(=O)n(CC(=O)OCC2CO2)c1=O ; CCCCn1c(=O)n(CC(=O)OCC2CO2)c(=O)n(CC(=O)OCC2CO2)c1=O ; C#CCn1c(=O)n(CC(=O)OCC2CO2)c(=O)n(CC(=O)OCC2CO2)c1=O ; COCCOCn1c(=O)n(CC(=O)OCC2CO2)c(=O)n(CC(=O)OCC2CO2)c1=O ; CSCn1c(=O)n(CC(=O)OCC2CO2)c(=O)n(CC(=O)OCC2CO2)c1=O]

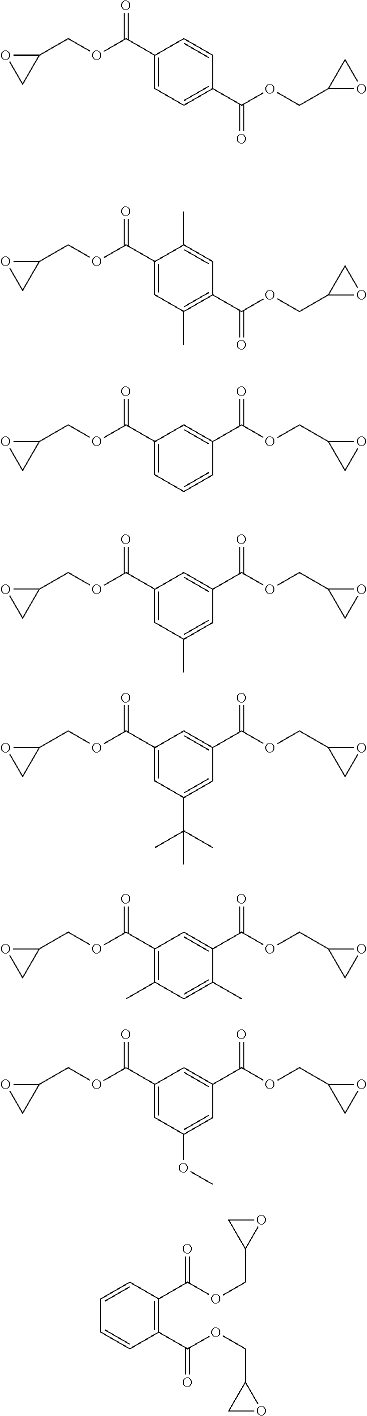

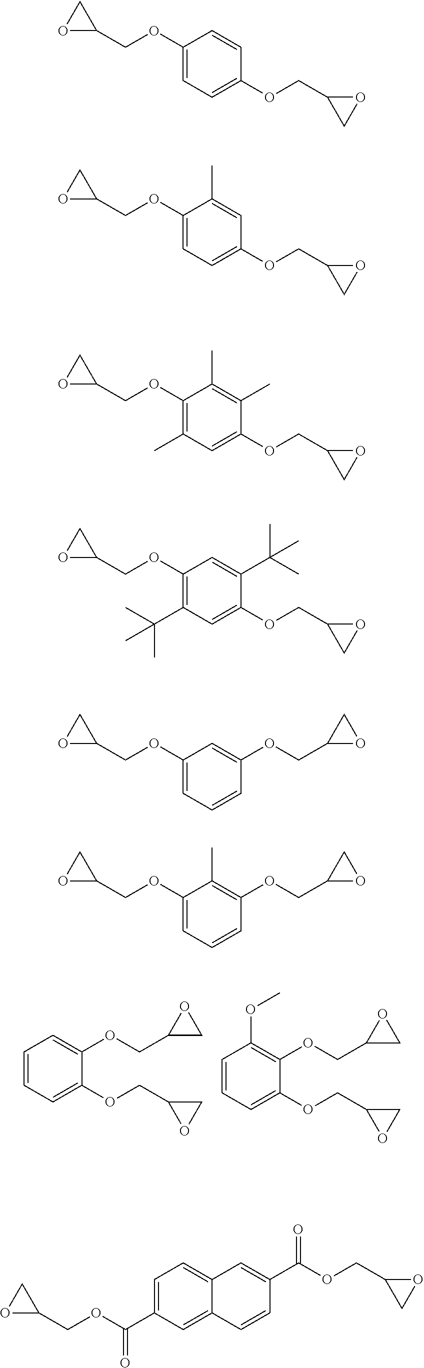

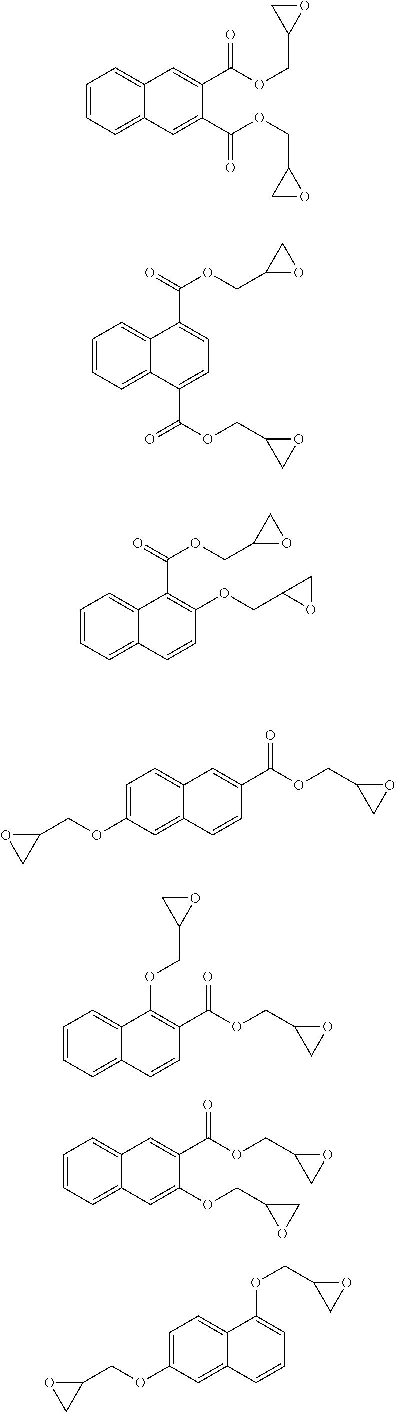

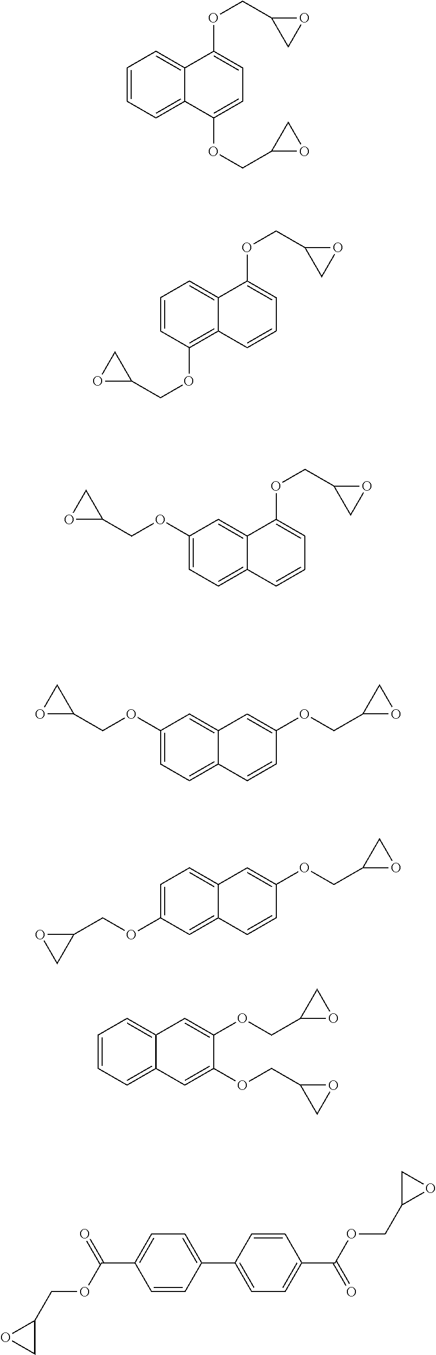

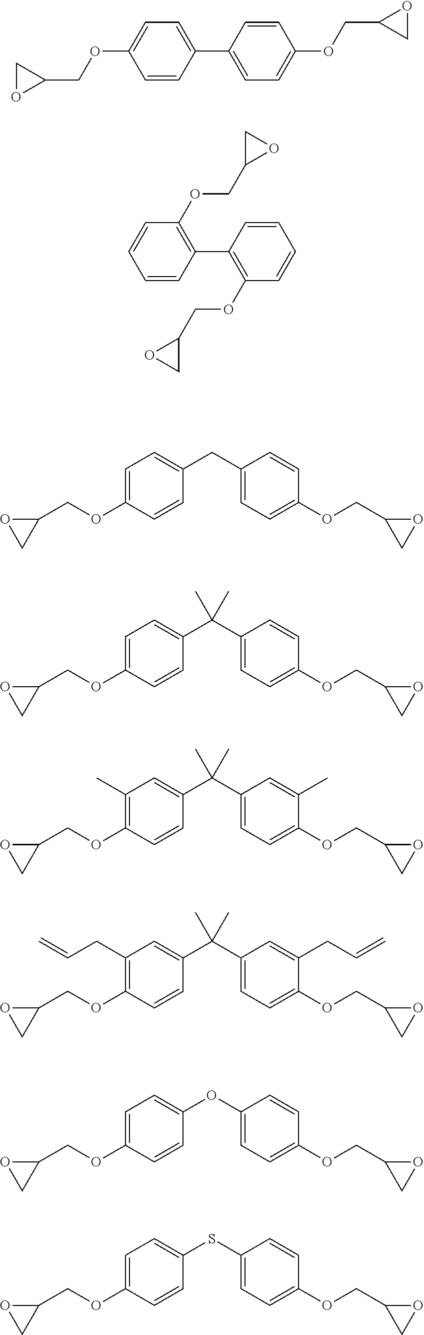

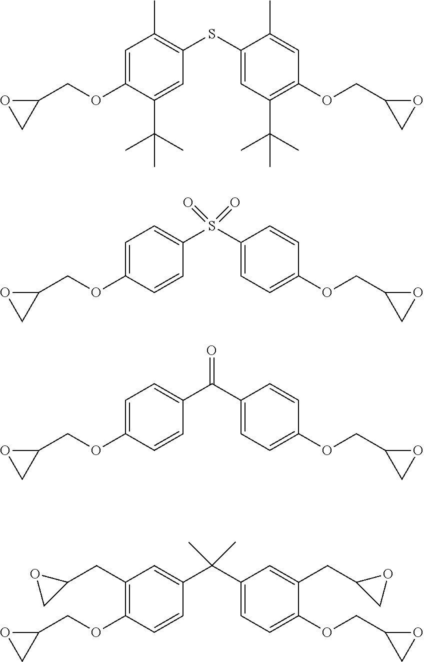 [SMILES: Cc1cc(OCC2CO2)c(C(C)(C)C)cc1Sc1cc(C(C)(C)C)c(OCC2CO2)cc1C ; O=S(=O)(c1ccc(OCC2CO2)cc1)c1ccc(OCC2CO2)cc1 ; O=C(c1ccc(OCC2CO2)cc1)c1ccc(OCC2CO2)cc1 ; CC(C)(c1ccc(OCC2CO2)c(CC2CO2)c1)c1ccc(OCC2CO2)c(CC2CO2)c1]

Examples of the compound represented by Formula (C) include the following compounds.

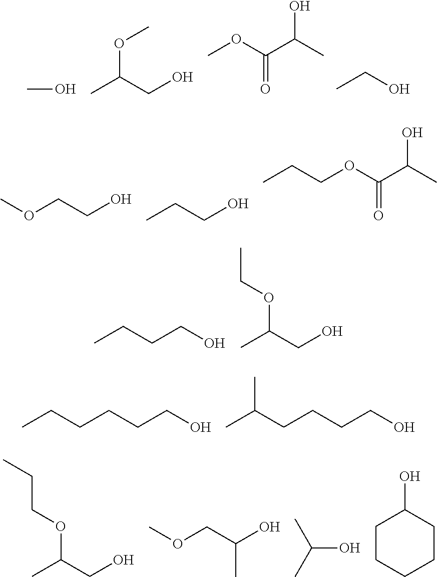

The weight average molecular weight Mw of the polymer is not particularly limited, but is preferably 1,000 to 50,000, more preferably 1, 500 to 30, 000, and particularly preferably 2,000 to 10,000.

In the present invention, the weight average molecular weight Mw is a value in terms of polystyrene measured by gel permeation chromatography (GPC).

### <Solvent>

The solvent used in the protective film forming composition is not particularly limited as long as it is a solvent capable of uniformly dissolving contained components that are solid at normal temperature, but generally, an organic solvent used in a chemical solution for a semiconductor lithography process is preferable. Specific examples include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxy cyclopentane, anisole, γ-butyrolactone, N-methylpyrrolidone, N,N-dimethylformamide, and N,N-dimethylacetamide. These solvents can be used singly, or in combination of two or more kinds thereof.

Among these solvents, propylene glycol monomethyl ether, propylene glycol monomethyl ether acetate, ethyl lactate, butyl lactate, and cyclohexanone are preferable. Propylene glycol monomethyl ether and propylene glycol monomethyl ether acetate are particularly preferable.

### <Crosslinking Agent>

Examples of the crosslinking agent contained as an optional component in the protective film forming composition include melamine-based crosslinking agents having an alkoxymethyl group, substituted urea-based crosslinking agents, and polymer systems thereof.

The alkoxy groups include an alkoxy group having 1 to 10 carbon atoms, and examples thereof include a methoxy group, an ethoxy group, a propoxy group, and a butoxy group. Examples of the methyl group having the alkoxy group include a methoxymethyl group, an ethoxymethyl group, a propoxymethyl group, and a butoxymethyl group. Preferably, the crosslinking agent is a crosslinking agent having at least two crosslinking forming substituents, and examples thereof include hexamethoxymethylmelamine, tetramethoxymethylbenzoguanamine, 1,3,4,6-tetrakis(methoxymethyl)glycoluril (tetramethoxymethylglycoluril) (POWDERLINK [registered trademark] 1174), 1,3,4,6-tetrakis (butoxymethyl)glycoluril, 1,3,4,6-tetrakis(hydroxymethyl)glycoluril, 1,3-bis(hydroxymethyl)urea, 1,1,3,3-tetrakis (butoxymethyl)urea, and 1,1,3,3-tetrakis(methoxymethyl)urea.

As the crosslinking agent, a crosslinking agent having high heat resistance can be used. As the crosslinking agent having high heat resistance, a compound containing a crosslinking substituent having an aromatic ring (for example, a benzene ring or a naphthalene ring) in the molecule can be used.

Examples of the compound include a compound having a partial structure of Formula (H-1) and a polymer or oligomer having a repeating unit of Formula (H-2).

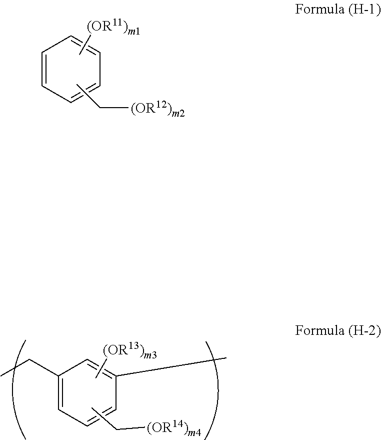

R¹¹, R¹², R¹³, and R¹⁴ are each a hydrogen atom or an alkyl group having 1 to 10 carbon atoms, and the above-described examples can be used for these alkyl groups.
m1 satisfies 1≤m1≤(6−m2).
m2 satisfies 1≤m2≤5.
m3 satisfies 1≤m3≤(4−m2).
m4 satisfies 1≤m4≤3.

The compounds, polymers, and oligomers of Formula (H-1) and Formula (H-2) are exemplified below.

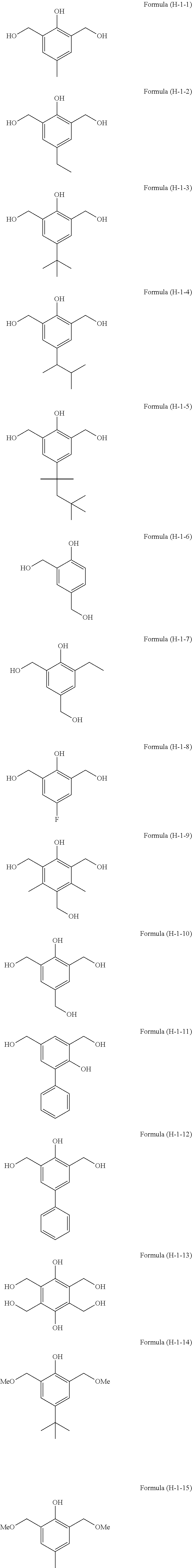

In the formula, Me is a methyl group.

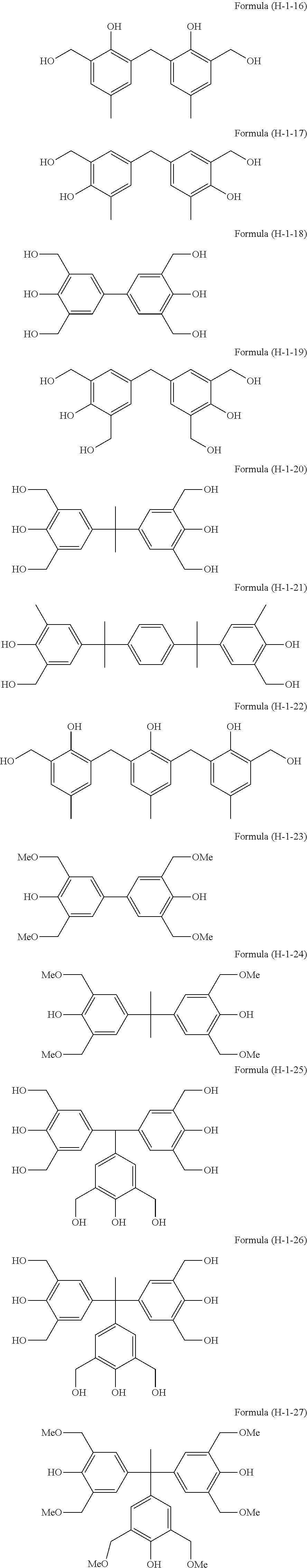

In the formula, Me is a methyl group.

The above compounds can be available as products of Asahi Organic Chemicals Industry Co., Ltd., and Honshu Chemical Industry Co., Ltd. For example, a compound of Formula (H-1-23) among the above crosslinking agents can be available as trade name TMOM-BP from Honshu Chemical Industry Co., Ltd. A compound of Formula (H-1-20) can be available as trade name TM-BIP-A from Asahi Organic Chemicals Industry Co., Ltd.

In addition, the crosslinking agent may be a nitrogen-containing compound having, in one molecule, 2 to 6 substituents represented by Formula (1d) that bond to a nitrogen atom, which is described in WO 2017/187969 A.

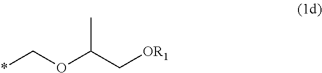

In Formula (1d), R₁ is a methyl group or an ethyl group, and * is a bond bonded to a nitrogen atom.

The nitrogen-containing compound having 2 to 6 substituents represented by Formula (1d) in one molecule may be a glycoluril derivative represented by Formula (1E).

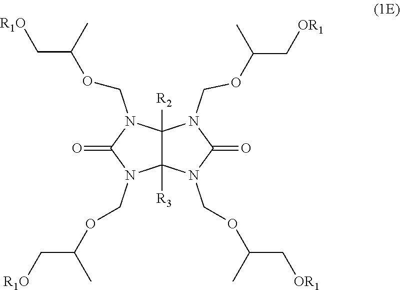

In Formula (1E), four R₁ are each independently a methyl group or an ethyl group, and R₂ and R₅ are each independently a hydrogen atom, an alkyl group having 1 to 4 carbon atoms, or a phenyl group.

Examples of the glycoluril derivative represented by Formula (1E) include compounds represented by Formula (1E-1) to Formula (1E-6).

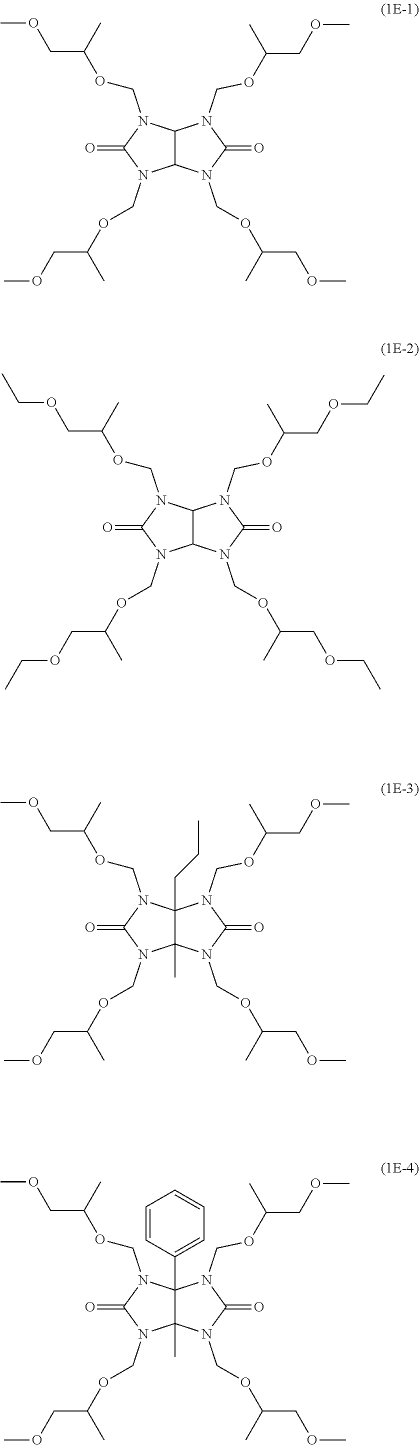

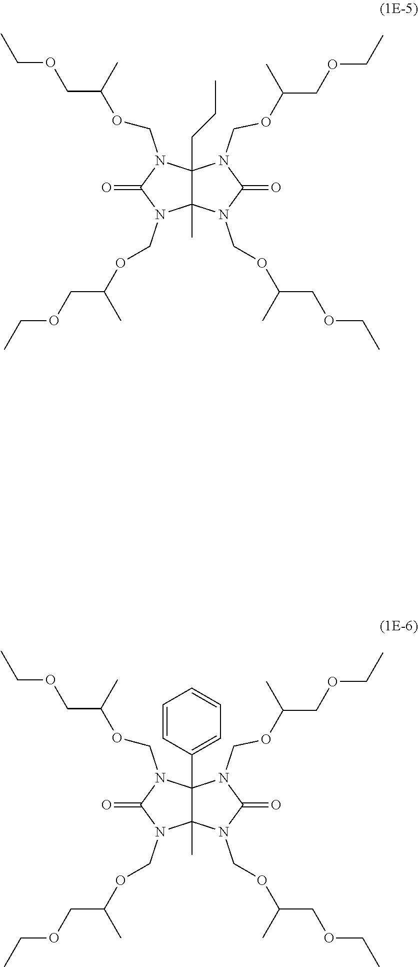

The nitrogen-containing compound having 2 to 6 substituents represented by Formula (1d) in one molecule is obtained by reacting a nitrogen-containing compound having, in one molecule, 2 to 6 substituents represented by Formula (2d) that bond to a nitrogen atom with at least one compound represented by Formula (3d).

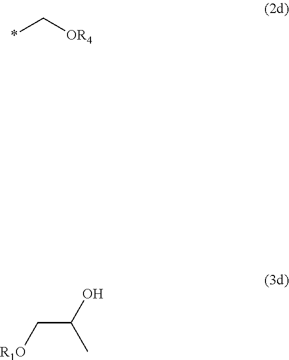

In Formula (2d) and Formula (3d), R₁ is a methyl group or an ethyl group, R₄ is an alkyl group having 1 to 4 carbon atoms, and * is a bond bonded to a nitrogen atom.

The glycoluril derivative represented by Formula (1E) is obtained by reacting a glycoluril derivative represented by Formula (2E) with at least one compound represented by Formula (3d).

The nitrogen-containing compound having 2 to 6 substituents represented by Formula (2d) in one molecule is, for example, a glycoluril derivative represented by Formula (2E).

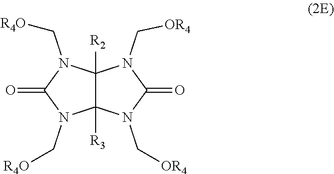

In Formula (2E), R₂ and R₅ are each independently a hydrogen atom, an alkyl group having 1 to 4 carbon atoms, or a phenyl group, and R₄ are each independently an alkyl group having 1 to 4 carbon atoms.

Examples of the glycoluril derivative represented by Formula (2E) include compounds represented by Formula (2E-1) to Formula (2E-4). Furthermore, examples of the compound represented by Formula (3d) include compounds represented by Formula (3d-1) and Formula (3d-2).

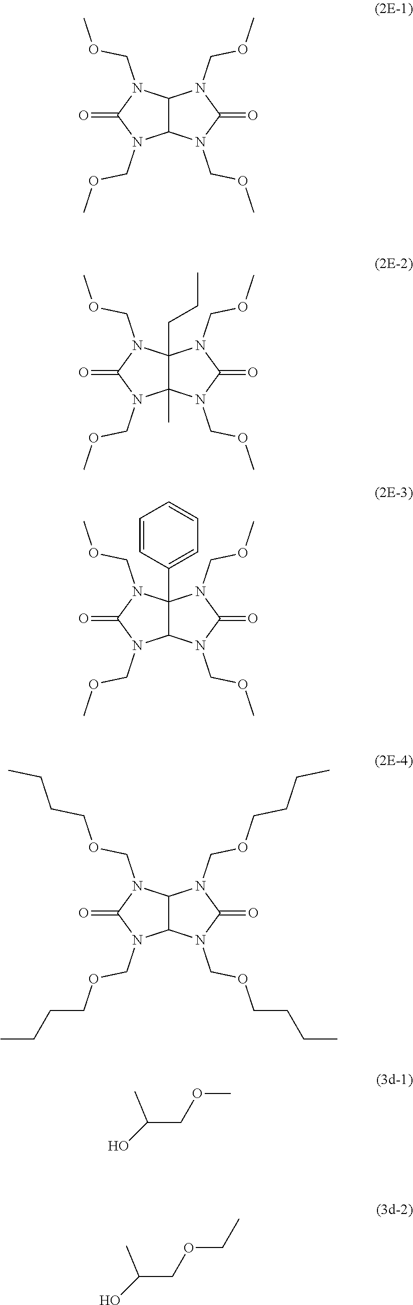

For the content related to the nitrogen-containing compound having, in one molecule, 2 to 6 substituents represented by Formula (1d) which bond to a nitrogen atom, the entire disclosure of WO2017/187969 A is incorporated herein by reference.

When a crosslinking agent is used, the content ratio of the crosslinking agent is, for example, 1 mass % to 50 mass %, preferably 5 mass % to 30 mass % with respect to the polymer having the partial structure represented by Formula (A).

### <Additive>

The protective film forming composition of the present invention can contain, as an optional component, a compound that is at least one of a compound represented by Formula (1a) and a compound represented by Formula (1b) in order to improve adhesion between a protective film formed of the protective film forming composition and a substrate.

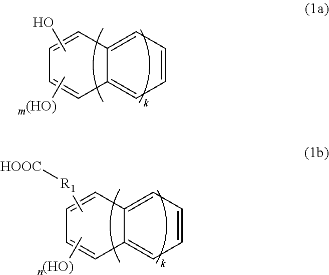

In Formulas (1a) and (1b), R₁ is a single bond, an alkylene group having 1 to 4 carbon atoms, or an alkenylene group having 2 to 4 carbon atoms which has one or two carbon-carbon double bonds, k is 0 or 1, m is an integer of 1 to 3, and n is an integer of 2 to 4.

Examples of the compound represented by Formula (1a) include compounds represented by Formula (1a-1) to Formula (1a-19).

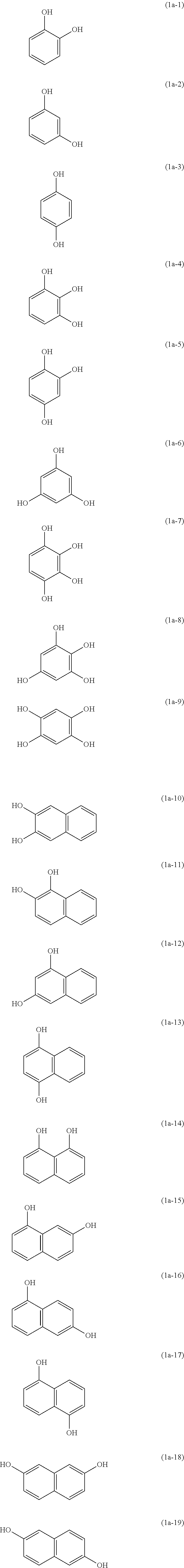

Examples of the compound represented by Formula (1b) include compounds represented by Formula (1b-1) to Formula (1b-31).

[chemical structure]

When a compound that is at least one of the compound represented by Formula (1a) and the compound represented by Formula (1b) is used, the content ratio of the compound is, for example, 1 mass % to 50 mass %, preferably 1 mass % to 30 mass %, and more preferably 1 mass % to 10 mass % with respect to the polymer having the partial structure represented by Formula (A).

### <Acid Generator>

As a curing catalyst contained as an optional component in the protective film forming composition, both a thermal acid generator and a photoacid generator can be used, but it is preferable to use a thermal acid generator.

Examples of the thermal acid generator include sulfonic acid compounds and carboxylic acid compounds such as p-toluenesulfonic acid, trifluoromethanesulfonic acid, pyridinium-p-toluenesulfonate (pyridinium-p-toluenesulfonic acid), pyridinium phenolsulfonate, pyridinium-p-hydroxybenzenesulfonate (p-phenolsulfonic acid pyridinium salt), pyridinium-trifluoromethanesulfonate, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generator include an onium salt compound, a sulfonimide compound, and a disulfonyl diazomethane compound.

Examples of the onium salt compound include iodonium salt compounds such as diphenyliodonium hexafluorophosphate, diphenyliodonium trifluoromethanesulfonate, diphenyliodonium nonafluoro-normal-butanesulfonate, diphenyliodonium perfluoro-normal-octanesulfonate, diphenyliodonium camphorsulfonate, bis(4-tert-butylphenyl)iodonium camphorsulfonate, and bis(4-tert-butylphenyl)iodonium trifluoromethanesulfonate, and sulfonium salt compounds such as triphenylsulfonium hexafluoroantimonate, triphenylsulfonium nonafluoro-normal-butanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoro-normal-butanesulfonyloxy)succinimide, N-(camphorsulfonyloxy)succinimide, and N-(trifluoromethanesulfonyloxy)naphthalimide.

Examples of the disulfonyl diazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyl diazomethane.

Only one kind of curing catalyst can be used, or two or more kinds thereof can be used in combination.

When a curing catalyst is used, the content ratio of the curing catalyst is, for example, 0.1 mass % to 50 mass %, preferably 1 mass % to 30 mass % with respect to the crosslinking agent.

### <Other Components>

To the protective film forming composition, a surfactant can be further added in order to prevent generation of pinholes, striations, or the like, and further improve the coating property for surface unevenness. Examples of the surfactant include nonionic surfactants, for example, polyoxyethylene alkyl ethers such as polyoxyethylene lauryl ether, polyoxyethylene stearyl ether, polyoxyethylene cetyl ether, and polyoxyethylene oleyl ether, polyoxyethylene alkylallyl ethers such as polyoxyethylene octylphenol ether and polyoxyethylene nonylphenol ether, polyoxyethylene/polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants such as EFTOP EF301, EF303, EF352 (trade name, manufactured by Tohkem Products Corporation), MEGAFACE F171, F173, R-30, and R-40 (trade name, manufactured by DIC Corporation,), Fluorad FC430 and FC431 (trade name, manufactured by Sumitomo 3M Limited), AsahiGuard AG710, Surflon S-382, SC101, SC102, SC103, SC104, SC105, and SC106 (trade name, manufactured by Asahi Glass Co., Ltd.); and organosiloxane polymer KP341 (manufactured by Shin-Etsu Chemical Co., Ltd.). The blending amount of these surfactants is usually 2.0 mass % or less, and preferably 1.0 mass % or less with respect to the total solid content of the protective film forming composition. These surfactants may be added singly, or may be added in combination of two or more kinds thereof.

The nonvolatile content of the protective film forming composition, that is, the components excluding the solvent is, for example, 0.01 mass % to 10 mass %.

(Protective Film, Method for Manufacturing Substrate with Protective Film, Method for Manufacturing Substrate with Resist Pattern, and Method for Manufacturing Semiconductor Device)

The protective film of the present invention is a baked product of a coating film formed of a protective film forming composition.

The method for manufacturing a substrate with a protective film of the present invention includes the step of applying the protective film forming composition of the present invention onto a semiconductor substrate having steps and baking the composition to form the protective film.

The method for manufacturing a substrate with a resist pattern according to the present invention includes the following steps (1) to (2).
Step (1): a step of applying the protective film forming composition of the present invention onto a semiconductor substrate and baking the composition to form a protective film as a resist underlayer film
Step (2): a step of forming a resist film directly on the protective film or with another layer interposed therebetween, and then performing exposure and development to form a resist pattern

A method for manufacturing a semiconductor device according to the present invention includes the following processes (A) to (D).
Process (A): a process of forming a protective film using the protective film forming composition of the present invention on a semiconductor substrate having an inorganic film formed on a surface thereof
Process (B): a process of forming a resist pattern directly on a protective film or with another layer interposed therebetween
Process (C): a process of dry etching the protective film using the resist pattern as a mask to expose the surface of the inorganic film
Process (D): a process of wet etching and cleaning the inorganic film with a semiconductor wet etching solution using the protective film after dry etching as a mask

Examples of the semiconductor substrate to which the protective film forming composition of the present invention is applied include silicon wafers, germanium wafers, and compound semiconductor wafers such as gallium arsenide, indium phosphide, gallium nitride, indium nitride, and aluminum nitride.

When a semiconductor substrate having an inorganic film formed on a surface thereof is used, the inorganic film is formed by, for example, an atomic layer deposition (ALD) method, a chemical vapor deposition (CVD) method, a reactive sputtering method, an ion plating method, a vacuum deposition method, or a spin coating method (spin on glass: SOG). Examples of the inorganic film include a polysilicon film, a silicon oxide film, a silicon nitride film, a silicon oxynitride film, a boro-phospho silicate glass (BPSG) film, a titanium nitride film, a titanium oxynitride film, a tungsten nitride film, a gallium nitride film, and a gallium arsenide film.

The semiconductor substrate may be a stepped substrate in which so-called vias (holes), trenches (grooves), and the like are formed. For example, the via has a substantially circular shape when viewed from the upper surface, the diameter of the substantially circular shape is, for example, 2 nm to 20 nm, and the depth is 50 nm to 500 nm, and with regard to the trench, the width of the groove (recess of the substrate) is, for example, 2 nm to 20 nm, and the depth is 50 nm to 500 nm.

Since the compounds contained in the protective film forming composition of the present invention have a small weight average molecular weight and average particle size, the stepped substrate as described above can also be filled with the composition without defects such as voids. It is an important characteristic that there is no defect such as a void, for the next steps of semiconductor manufacturing (wet etching/dry etching of semiconductor substrate, resist pattern formation).

The protective film forming composition of the present invention is applied onto such a semiconductor substrate by an appropriate application method such as a spinner or a coater. Thereafter, the protective film is formed by baking using a heating means such as a hot plate. The baking conditions are appropriately selected from a baking temperature of 100° C. to 400° C. and a baking time of 0.3 minutes to 60 minutes. They are preferably a baking temperature of 120° C. to 350° C. and a baking time of 0.5 minutes to 30 minutes, and more preferably a baking temperature of 150° C. to 300° C. and a baking time of 0.8 minutes to 10 minutes. The thickness of the protective film to be formed is, for example, 0.001 μm to 10 μm, preferably 0.002 μm to 1 μm, and more preferably 0.005 μm to 0.5 μm. When the temperature at the time of baking is lower than the above range, crosslinking becomes insufficient, and thus resistance of the protective film to be formed to a resist solvent or a basic hydrogen peroxide aqueous solution may be difficult to obtain. On the other hand, when the temperature at the time of baking is higher than the above range, the protective film may be decomposed by heat.

A resist film is formed directly on the protective film formed as described above or with another layer interposed therebetween, and then exposed and developed to form a resist pattern.

The exposure is performed through a mask (reticle) for forming a predetermined pattern, and for example, i-line, KrF excimer laser, ArF excimer laser, extreme ultraviolet (EUV), or electron beam (EB) is used. An alkaline developer is used for development, and the conditions are appropriately selected from a development temperature of 5° C. to 50° C. and a development time of 10 seconds to 300 seconds. As the alkaline developer, it is possible to use an aqueous solution of an alkali, for example, an inorganic alkali such as sodium hydroxide, potassium hydroxide, sodium carbonate, sodium silicate, sodium metasilicate, or ammonia water, a primary amine such as ethylamine or n-propylamine, a secondary amine such as diethylamine or di-n-butylamine, a tertiary amine such as triethylamine or methyldiethylamine, an alcoholamine such as dimethylethanolamine or triethanolamine, a quaternary ammonium salt such as tetramethylammonium hydroxide, tetraethylammonium hydroxide, or choline, a cyclic amine such as pyrrole or piperidine, or the like. Furthermore, it is also possible to add an appropriate amount of an alcohol such as isopropyl alcohol or a surfactant such as a nonionic surfactant to the aqueous solution of the alkali prior to use. Among them, preferred developers are quaternary ammonium salts, more preferably tetramethylammonium hydroxide and choline. Furthermore, a surfactant or the like can be added to these developers. It is also possible to use a method of performing development with an organic solvent such as butyl acetate instead of the alkaline developer, to develop a portion where the alkali dissolution rate of the photoresist is not improved.

Next, the protective film is dry-etched using the formed resist pattern as a mask. At that time, when the inorganic film is formed on the surface of the used semiconductor substrate, the surface of the inorganic film is exposed, and when the inorganic film is not formed on the surface of the used semiconductor substrate, the surface of the semiconductor substrate is exposed.

Further, a desired pattern is formed by wet etching with a semiconductor wet etching solution using the protective film after dry etching as a mask (when a resist pattern remains on the protective film, the resist pattern is also used as a mask).

As the semiconductor wet etching solution, a general chemical solution for etching a semiconductor wafer can be used, and for example, both a substance exhibiting acidity and a substance exhibiting basicity can be used.

Examples of the substance exhibiting acidity include hydrogen peroxide, hydrofluoric acid, ammonium fluoride, acidic ammonium fluoride, ammonium hydrogen fluoride, buffered hydrofluoric acid, hydrochloric acid, nitric acid, sulfuric acid, phosphoric acid, and a mixed solution thereof.

Examples of the substance exhibiting basicity include ammonia, sodium hydroxide, potassium hydroxide, sodium cyanide, potassium cyanide, and a basic hydrogen peroxide solution obtained by mixing an organic amine such as triethanolamine with a hydrogen peroxide solution to make the pH basic. Specific examples thereof include SC-1 (ammonia-hydrogen peroxide solution). In addition, those capable of making the pH basic, for example, those in which urea and a hydrogen peroxide solution are mixed and heated to cause thermal decomposition of the urea, thereby generating ammonia that finally makes the pH basic, can also be used as a chemical solution for wet etching.

Among them, an acidic hydrogen peroxide solution or a basic hydrogen peroxide solution is preferable.

These chemical solutions may contain an additive such as a surfactant.

The temperature during use of the semiconductor wet etching solution is desirably 25° C. to 90° C., and more desirably 40° C. to 80° C. The wet etching time is desirably 0.5 minutes to 30 minutes, and more desirably 1 minute to 20 minutes.

### EXAMPLES

Next, the contents of the present invention will be specifically described with reference to synthesis examples and examples, but the present invention is not limited thereto.

The weight average molecular weights of the polymers shown in the following Synthesis Examples 1 to 5 are measurement results by gel permeation chromatography (hereinafter, abbreviated as GPC). For the measurement, a GPC instrument manufactured by Tosoh Corporation was used, and measurement conditions and the like are as follows.
Column temperature: 40° C.
Flow rate: 0.35 ml/min
Eluent: tetrahydrofuran (THF)
Standard sample: polystyrene (Tosoh Corporation)

### Synthesis Example 1

To 3.00 g of monoallyl diglycidyl isocyanurate (product name: MA-DGIC, manufactured by Shikoku Chemicals Corporation), 1.45 g of 3,3′4,4′-benzophenonetetracarboxylic dianhydride (manufactured by Tokyo Chemical Industry Co., Ltd.), 0.80 g of succinic acid (manufactured by Tokyo Chemical Industry Co., Ltd.), and 0.09 g of tetrabutylphosphonium bromide (manufactured by Hokko Chemical Industry Co., Ltd.) in a reaction flask, 21.97 g of propylene glycol monomethyl ether was added. The obtained mixture was heated and stirred in the reaction flask at 120° C. for 5 hours under a nitrogen atmosphere. The obtained reaction product corresponded to Formula (x-1), and the weight average molecular weight Mw thereof measured in terms of polystyrene by GPC was 3380.

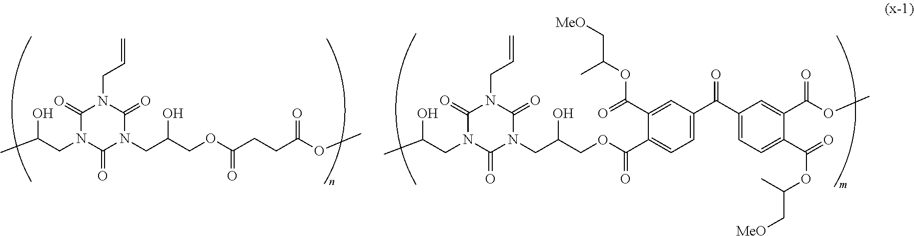

In the formula, Me is a methyl group.

### Synthesis Example 2

To 3.00 g of monoallyl diglycidyl isocyanurate (product name: MA-DGIC, manufactured by Shikoku Chemicals Corporation), 1.61 g of 3,3′, 4,4′-diphenylsulfonetetracarboxylic dianhydride (manufactured by Tokyo Chemical Industry Co., Ltd.), 0.80 g of succinic acid (manufactured by Tokyo Chemical Industry Co., Ltd.), and 0.09 g of tetrabutylphosphonium bromide (manufactured by Hokko Chemical Industry Co., Ltd.) in a reaction flask, 22.62 g of propylene glycol monomethyl ether was added. The obtained mixture was heated and stirred in the reaction flask at 120° C. for 5 hours under a nitrogen atmosphere. The obtained reaction product corresponded to Formula (x-2), and the weight average molecular weight Mw thereof measured in terms of polystyrene by GPC was 5220.

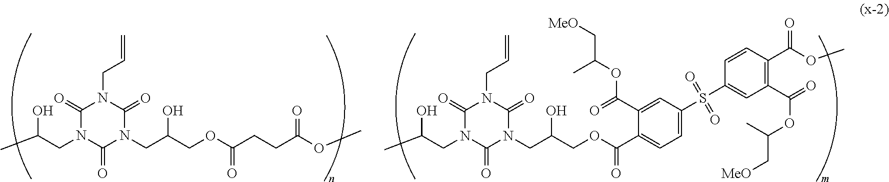

In the formula, Me is a methyl group.

### Synthesis Example 3

To 3.00 g of monoallyl diglycidyl isocyanurate (product name: MA-DGIC, manufactured by Shikoku Chemicals Corporation), 0.87 g of trimellitic anhydride (manufactured by Tokyo Chemical Industry Co., Ltd.), 0.80 g of succinic acid (manufactured by Tokyo Chemical Industry Co., Ltd.), and 0.09 g of tetrabutylphosphonium bromide (manufactured by Hokko Chemical Industry Co., Ltd.) in a reaction flask, 19.63 g of propylene glycol monomethyl ether was added. The obtained mixture was heated and stirred in the reaction flask at 120° C. for 5 hours under a nitrogen atmosphere. The obtained reaction product corresponded to Formula (x-3), and the weight average molecular weight Mw thereof measured in terms of polystyrene by GPC was 2830.

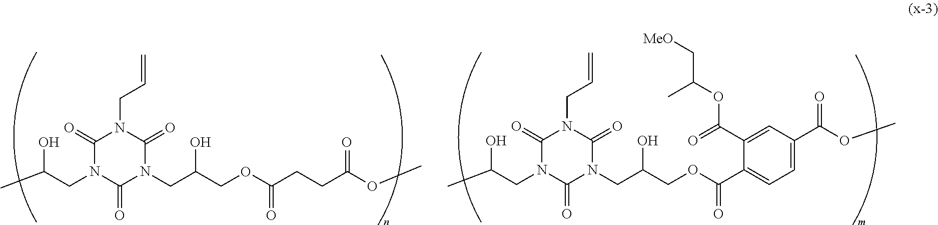

In the formula, Me is a methyl group.

### Synthesis Example 4

To 3.00 g of monoallyl diglycidyl isocyanurate (product name: MA-DGIC, manufactured by Shikoku Chemicals Corporation), 0.44 g of 1,2,3,4-cyclobutanetetracarboxylic dianhydride (manufactured by Tokyo Chemical Industry Co., Ltd.), 1.06 g of succinic acid (manufactured by Tokyo Chemical Industry Co., Ltd.), and 0.09 g of tetrabutylphosphonium bromide (manufactured by Hokko Chemical Industry Co., Ltd.) in a reaction flask, 19.00 g of propylene glycol monomethyl ether was added. The obtained mixture was heated and stirred in the reaction flask at 120° C. for 5 hours under a nitrogen atmosphere. The obtained reaction product corresponded to Formula (x-4), and the weight average molecular weight Mw thereof measured in terms of polystyrene by GPC was 2340.

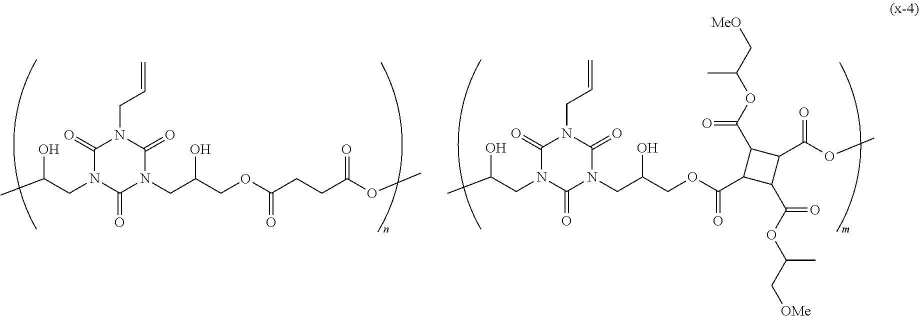

In the formula, Me is a methyl group.

### Synthesis Example 5

To 3.00 g of monoallyl diglycidyl isocyanurate (product name: MA-DGIC, manufactured by Shikoku Chemicals Corporation), 0.44 g of 1,2,3,4-cyclobutanetetracarboxylic dianhydride (manufactured by Tokyo Chemical Industry Co., Ltd.), 1.18 g of glutaric acid (manufactured by Tokyo Chemical Industry Co., Ltd.), and 0.09 g of tetrabutylphosphonium bromide (manufactured by Hokko Chemical Industry Co., Ltd.) in a reaction flask, 19.50 g of propylene glycol monomethyl ether was added. The obtained mixture was heated and stirred in the reaction flask at 120° C. for 5 hours under a nitrogen atmosphere. The obtained reaction product corresponded to Formula (x-5), and the weight average molecular weight Mw thereof measured in terms of polystyrene by GPC was 3910.

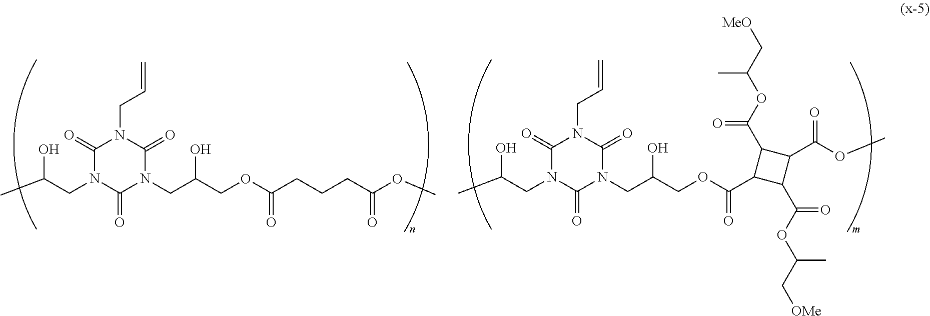

### Example 1

To 7.36 g of a solution of the reaction product corresponding to Formula (X-1) (solid content: 18.6 mass %), 0.26 g of 3,3′,5,5′-tetrakis(methoxymethyl)-4,4′-dihydroxybiphenyl (product name: TMOM-BP, manufactured by Honshu Chemical Industry Co., Ltd.), 0.04 g of pyridinium trifluoromethanesulfonate (manufactured by Tokyo Chemical Industry Co., Ltd.), 0.01 g of a surfactant (product name: MEGAFACE R-40, manufactured by DIC Corporation), 19.48 g of propylene glycol monomethyl ether, and 2.84 g of propylene glycol monomethyl ether acetate were added to prepare a solution. The solution was filtered through a polyethylene microfilter having a pore size of 0.02 μm to prepare a protective film forming composition.

### Example 2

To 7.39 g of a solution of the reaction product corresponding to Formula (X-2) (solid content: 18.5 mass %), 0.26 g of 3,3′,5,5′-tetrakis(methoxymethyl)-4,4′-dihydroxybiphenyl (product name: TMOM-BP, manufactured by Honshu Chemical Industry Co., Ltd.), 0.04 g of pyridinium trifluoromethanesulfonate (manufactured by Tokyo Chemical Industry Co., Ltd.), 0.01 g of a surfactant (product name: MEGAFACE R-40, manufactured by DIC Corporation), 19.45 g of propylene glycol monomethyl ether, and 2.84 g of propylene glycol monomethyl ether acetate were added to prepare a solution. The solution was filtered through a polyethylene microfilter having a pore size of 0.02 μm to prepare a protective film forming composition.

### Example 3

To 7.71 g of a solution of the reaction product corresponding to Formula (X-3) (solid content: 17.7 mass %), 0.26 g of 3,3′,5,5′-tetrakis(methoxymethyl)-4,4′-dihydroxybiphenyl (product name: TMOM-BP, manufactured by Honshu Chemical Industry Co., Ltd.), 0.04 g of pyridinium trifluoromethanesulfonate (manufactured by Tokyo Chemical Industry Co., Ltd.), 0.01 g of a surfactant (product name: MEGAFACE R-40, manufactured by DIC Corporation), 19.12 g of propylene glycol monomethyl ether, and 2.84 g of propylene glycol monomethyl ether acetate were added to prepare a solution. The solution was filtered through a polyethylene microfilter having a pore size of 0.02 μm to prepare a protective film forming composition.

### Example 4

To 7.93 g of a solution of the reaction product corresponding to Formula (X-4) (solid content: 17.2 mass %), 0.26 g of 3,3′,5,5′-tetrakis(methoxymethyl)-4,4′-dihydroxybiphenyl (product name: TMOM-BP, manufactured by Honshu Chemical Industry Co., Ltd.), 0.06 g of pyridinium trifluoromethanesulfonate (manufactured by Tokyo Chemical Industry Co., Ltd.), 0.01 g of a surfactant (product name: MEGAFACE R-40, manufactured by DIC Corporation), 18.90 g of propylene glycol monomethyl ether, and 2.84 g of propylene glycol monomethyl ether acetate were added to prepare a solution. The solution was filtered through a polyethylene microfilter having a pore size of 0.02 μm to prepare a protective film forming composition.

### Example 5

To 7.71 g of a solution of the reaction product corresponding to Formula (X-5) (solid content: 17.7 mass %), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.06 g of pyridinium trifluoromethanesulfonate (manufactured by Tokyo Chemical Industry Co., Ltd.), 0.01 g of a surfactant (product name: MEGAFACE R-40, manufactured by DIC Corporation), 19.12 g of propylene glycol monomethyl ether, and 2.84 g of propylene glycol monomethyl ether acetate were added to prepare a solution. The solution was filtered through a polyethylene microfilter having a pore size of 0.02 μm to prepare a protective film forming composition.

### Example 6

To 7.76 g of a solution of the reaction product corresponding to Formula (X-4) (solid content: 17.2 mass %), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonate (manufactured by Tokyo Chemical Industry Co., Ltd.), 0.04 g of gallic acid, 0.01 g of a surfactant (product name: MEGAFACE R-40, manufactured by DIC Corporation), 19.16 g of propylene glycol monomethyl ether, and 2.84 g of propylene glycol monomethyl ether acetate were added to prepare a solution. The solution was filtered through a polyethylene microfilter having a pore size of 0.02 μm to prepare a protective film forming composition.

### Comparative Example 1

To 8.25 g of a solution of a reaction product obtained by the method described in Synthesis Example 12 of WO2020/026834 (a copolymer corresponding to Formula (1n) and having a weight average molecular weight of 4500 as measured in terms of polystyrene by GPC) (solid content: 16.4 mass %), 0.05 g of pyridinium trifluoromethanesulfonate (manufactured by Tokyo Chemical Industry Co., Ltd.), 0.01 g of a surfactant (product name: MEGAFACE R-40, manufactured by DIC Corporation), 18.05 g of propylene glycol monomethyl ether, and 2.84 g of propylene glycol monomethyl ether acetate were added to prepare a solution. The solution was filtered through a polyethylene microfilter having a pore size of 0.02 μm to prepare a protective film forming composition.

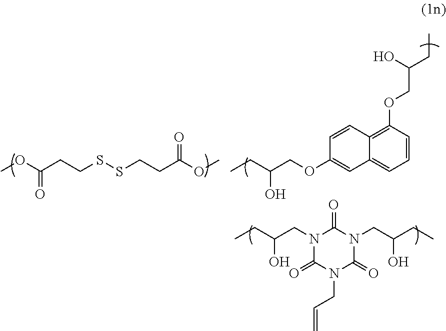

### [Resist Solvent Resistance Test]

Each of the protective film forming compositions prepared in Examples 1 to 6 and Comparative Example 1 was applied (spin coated) onto a silicon wafer with a spin coater. The silicon wafer after application was heated on a hot plate at 220° C. for 1 minute to form a coating (protective film) having a thickness of 150 nm. Next, in order to confirm solvent resistance of the protective film, the silicon wafer on which the protective film had been formed was immersed for 1 minute in a mixed solvent obtained by mixing propylene glycol monomethyl ether and propylene glycol monomethyl ether acetate at a mass ratio of 7:3, spin-dried, and then baked at 100° C. for 30 seconds. The film thickness of the protective film before and after immersion in the mixed solvent was measured with an optical interferometry film thickness gauge (product name: NanoSpec 6100, manufactured by Nanometrics Japan Ltd.).

In the evaluation of solvent resistance, the film thickness reduction rate (%) of the protective film due to removal by solvent immersion was calculated and evaluated from the following calculation formula.

Film thickness reduction rate (%)=((A−B)÷A)×100
A: Film thickness before solvent immersion
B: Film thickness after solvent immersion

The results are shown in Table 1. When the film thickness reduction rate is about 1% or less, it can be said that the film has sufficient solvent resistance.

TABLE 1

| Example | Film thickness reduction rate |
|---|---|
| Example 1 | 0.1% |
| Example 2 | 0.0% |
| Example 3 | 0.2% |
| Example 4 | 0.0% |
| Example 5 | 0.0% |
| Example 6 | 0.0% |
| Comparative Example 1 | 0.3% |

From the above results, the protective film forming compositions of Examples 1 to 6 and Comparative Example 1 had a very small change in film thickness after immersion in a solvent. Thus, the protective film forming compositions of Examples 1 to 6 have sufficient solvent resistance to function as a protective film.

### [Test for Resistance to Hydrogen Peroxide Solution]

As an evaluation of resistance to a hydrogen peroxide solution, each of the protective film forming compositions in Examples 1 to 6 and Comparative Example 1 was applied onto a substrate having 50 nm thick titanium nitride (TiN) deposited, and heated at 220° C. for 1 minute to form a protective film having a thickness of 150 nm. Next, 20 mass % hydrogen peroxide was prepared. The TiN deposited substrate that had coated with the protective film forming composition was immersed in this 20 mass % hydrogen peroxide solution heated to 70° C., and the time from immediately after the immersion until the coating film (protective film) was fogged or damaged was measured. The results of the test for resistance to the hydrogen peroxide solution are shown in Table 2. It can be said that the longer the resistance time, the higher the resistance to the wet etching solution using the hydrogen peroxide solution.

TABLE 2

| Example | Resistance time of protective film | |
|---|---|---|
| Example 1 | 300 | sec |
| Example 2 | 250 | sec |
| Example 3 | 300 | sec |
| Example 4 | 300 | sec |
| Example 5 | 300 | sec |
| Example 6 | 350 | sec |
| Comparative Example 1 | 50 | sec |

From the results in the above table, it was shown that the coating films produced using the protective film forming compositions prepared in Examples 1 to 6 have sufficient resistance to the hydrogen peroxide aqueous solution. That is, it was found that these coating films can serve as a protective film against a hydrogen peroxide aqueous solution. In addition, it can be said that they exhibit good resistance to a wet etching solution using a hydrogen peroxide solution as compared with that in Comparative Example 1. Thus, since Examples 1 to 6 exhibit good chemical resistance to a hydrogen peroxide solution as compared with Comparative Example 1, they are useful as a protective film against a semiconductor wet etching solution.

### [Evaluation of Ability of Filling Substrate for Filling Ability Evaluation]

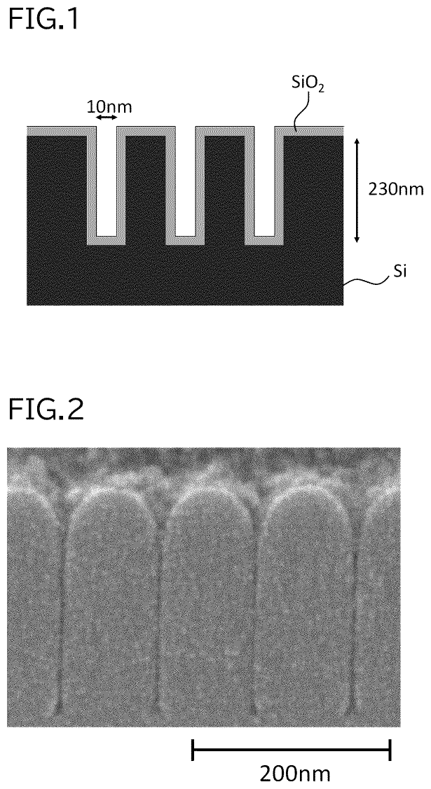

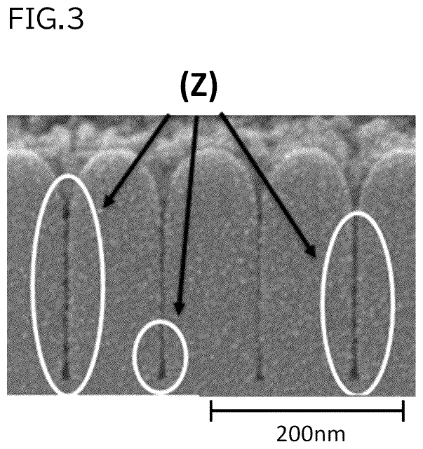

A processed silicon substrate was produced by depositing a silicon oxide film of about 20 nm using a chemical vapor deposition (CVD) method on a silicon substrate in which 50 nm trenches (L (line)/S (space)) had been formed, and the processed silicon substrate had a silicon oxide film formed on the trench surface portion. The protective film forming composition of Example 5 was applied onto the processed silicon substrate (after silicon oxide film deposition: 10 nm trenches (L (line)/S (space)). Thereafter, heating was performed on a hot plate at 220° C. for 1 minute to form a protective film having a film thickness of about 150 nm. Using a scanning electron microscope (SEM), the cross-sectional shape of the substrate with trenches (FIG. 1) on which the protective film had been formed was observed to evaluate filling ability. In the protective film forming composition of Example 5, it can be seen that the substrate with 10 nm trenches (L (line)/S (space)), which are gaps between silicon oxide films, is filled with the composition without generation of voids and the like (FIG. 2). For reference, a photograph of the case of filling failure is shown in FIG. 3. A portion (Z) surrounded by a white circle in FIG. 3 is a portion where a filling failure occurred.

1. A protective film forming composition for forming a protective film that protects an inorganic film formed on a surface of a semiconductor substrate against wet etching, the protective film forming composition comprising:
a polymer having a partial structure represented by Formula (A) and a solvent, 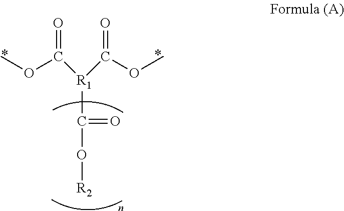
in Formula (A), R₁ is an (n+2)-valent organic group, R₂ is a hydrogen atom or an alkyl group having 1 to 13 carbon atoms which may be substituted with at least one group selected from the group consisting of an alkoxy group having 1 to 13 carbon atoms, an alkylcarbonyloxy group having 2 to 13 carbon atoms, an alkoxycarbonyl group having 2 to 13 carbon atoms, an alkylthio group having 1 to 13 carbon atoms, a nitro group, an alkylsulfonyloxy group having 1 to 13 carbon atoms, and an alkoxysulfonyl group having 1 to 13 carbon atoms, n is 1 or 2, when n is 2, two R₂ may be same or different, and * is a bond.

2. The protective film forming composition according to claim 1, wherein the polymer has a repeating unit represented by Formula (1): 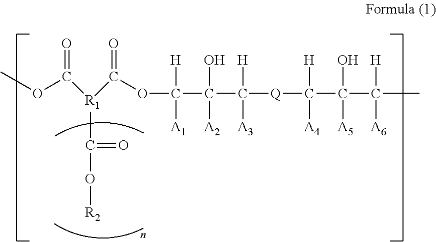
in Formula (1), A₁, A₂, A₃, A₄, A₅, and A₆ are each independently a hydrogen atom, a methyl group, or an ethyl group, Q is a divalent organic group, R₁ is an (n+2)-valent organic group, R₂ is a hydrogen atom or an alkyl group having 1 to 13 carbon atoms which may be substituted with at least one group selected from the group consisting of an alkoxy group having 1 to 13 carbon atoms, an alkylcarbonyloxy group having 2 to 13 carbon atoms, an alkoxycarbonyl group having 2 to 13 carbon atoms, an alkylthio group having 1 to 13 carbon atoms, a nitro group, an alkylsulfonyloxy group having 1 to 13 carbon atoms, and an alkoxysulfonyl group having 1 to 13 carbon atoms, n is 1 or 2, and when n is 2, two R₂ may be same or different.

3. The protective film forming composition according to claim 1, wherein the polymer further has a partial structure represented by Formula (B) different from the partial structure represented by Formula (A), 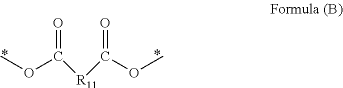
in Formula (B), R₁₁ is a divalent organic group, and * is a bond.

4. The protective film forming composition according to claim 2, wherein Q in Formula (1) is a divalent organic group represented by Formula (3): 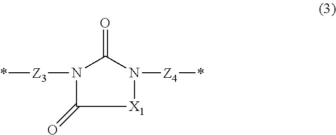
in Formula (3), X₁ is a divalent group represented by Formula (4), Formula (5), or Formula (6), Z₃ and Z₄ are each independently a direct bond or a divalent group represented by Formula (7), and * is a bond, 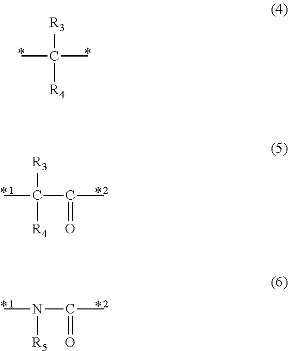
in Formulas (5) and (6), R³ and R₄ are each independently a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group, or a phenyl group, the phenyl group may be substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R₃ and R₄ may be bonded to each other to form a ring having 3 to 6 carbon atoms, * is a bond, *1 is a bond bonded to a carbon atom, and *2 is a bond bonded to a nitrogen atom,
in Formula (6), R₅ is a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group, or a phenyl group, the phenyl group may be substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, *1 is a bond bonded to a carbon atom, and *2 is a bond bonded to a nitrogen atom, 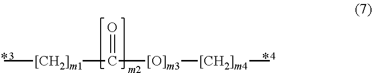
in Formula (7), m1 is an integer of 0 to 4, m2 is 0 or 1, m3 is 0 or 1, m4 is an integer of 0 to 2, provided that when m3 is 1, m1 and m2 do not simultaneously become 0, *3 is a bond bonded to a nitrogen atom, and *4 is a bond bonded to a carbon atom.

5. The protective film forming composition according to claim 1, further comprising a crosslinking agent.

6. The protective film forming composition according to claim 1, further comprising a compound that is at least one of a compound represented by Formula (1a) and a compound represented by Formula (1b): 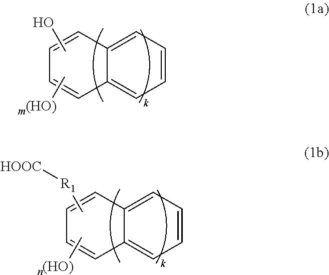
in Formulas (la) and (1b), R₁ is a single bond, an alkylene group having 1 to 4 carbon atoms, or an alkenylene group having 2 to 4 carbon atoms which has one or two carbon-carbon double bonds, k is 0 or 1, m is an integer of 1 to 3, and n is an integer of 2 to 4.

7. A protective film against a semiconductor wet etching solution, the protective film being a baked product of a coating film formed of the protective film forming composition according to claim 1.

8. A method for manufacturing a substrate with a protective film, the method comprising the step of applying the protective film forming composition according to claim 1 onto a semiconductor substrate having steps and baking the protective film forming composition to form the protective film.

9. A method for manufacturing a substrate with a resist pattern that is used in semiconductor manufacturing, the method comprising:
a step of applying the protective film forming composition according to claim 1 onto a semiconductor substrate and baking the protective film forming composition to form a protective film as a resist underlayer film; and
a step of forming a resist film directly on the protective film or with another layer interposed between the resist film and the protective film, and then performing exposure and development to form the resist pattern.

10. A method for manufacturing a semiconductor device, the method comprising: a step of forming a protective film using the protective film forming composition according to claim 1 on a semiconductor substrate having an inorganic film formed on a surface; a step of forming a resist pattern directly on the protective film or with another layer interposed between the resist pattern and the protective film; a step of dry etching the protective film using the resist pattern as a mask to expose a surface of the inorganic film; and a step of wet etching and cleaning the inorganic film with a semiconductor wet etching solution using the protective film after dry etching as a mask.
